(19) United States
(12) Patent Application Publication
(10) Pub. No.: US 2026/0344371 A1
(43) Pub. Date: Oct. 29, 2026

(54) REDISTRIBUTION INTERPOSER FOR PACKAGE AND METHOD OF FORMING SAME

(71) Applicant: Taiwan Semiconductor Manufacturing Co., Ltd., Hsinchu (TW)

(72) Inventors: Hsin-Yu Chen, Taipei City (TW); Hsiang-Hou Tseng, Hsinchu (TW); Meng-Wei Chou, Zhubei City (TW); Yu-Hsiang Hu, Hsinchu (TW); Chien-Hsun Lee, Chu-tung Town (TW)

(21) Appl. No.: 19/737,110

(22) Filed: Jul. 10, 2026

Related U.S. Application Data
(63) Continuation of application No. 18/936,704, filed on Nov. 4, 2024.
(60) Provisional application No. 63/667,174, filed on Jul. 3, 2024.

(51) Int. Cl. H10P 76/20; H10P 50/00; H10W 70/05; H10W 70/65; H10W 70/685; H10W 90/00

(52) U.S. Cl. CPC H10P 76/2041; H10P 50/73; H10W 70/05; H10W 70/65; H10W 70/685; H10W 90/701

(57) ABSTRACT

A method includes forming a first photoresist layer on a dielectric layer; performing a first light-exposure process on the first photoresist layer using a first photolithography mask, wherein during the first light-exposure process, a first region the first photoresist layer is blocked from being exposed, a second region of the first photoresist layer is exposed, and a third region of the first photoresist layer is exposed, wherein the second region encircles the first region and the third region encircles the second region; performing a second light-exposure process on the first photoresist layer using a second photolithography mask, wherein during the second light-exposure process, the first region of the first photoresist layer is exposed, the second region of the first photoresist layer is exposed, and the third region of the first photoresist layer is blocked from being exposed; and developing the first photoresist layer.

### PRIORITY CLAIM AND CROSS-REFERENCE

This application is a continuation of U.S. patent application Ser. No. 18/936,704, filed on Nov. 4, 2024, which claims the benefit of U.S. Provisional Application No. 63/667,174, filed on Jul. 3, 2024, each application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example is a Chip-On-Wafer-On-Substrate (CoWoS) structure, in which one or more semiconductor devices are attached to an interposer, which is then attached to a package substrate (e.g., a printed circuit board).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 16 illustrate cross-sectional views of intermediate steps during a process for forming a redistribution interposer, in accordance with some embodiments.

FIG. 17 illustrates a cross-sectional view of an intermediate step in the formation of a redistribution interposer, in accordance with some embodiments.

FIGS. 18 and 19 illustrate plan views of intermediate steps in the formation of a redistribution interposer, in accordance with some embodiments.

FIGS. 20 through 31 illustrate plan views of intermediate steps in the formation of redistribution interposers, in accordance with some embodiments.

FIGS. 32 through 44 illustrate cross-sectional views of intermediate steps during a process for forming a redistribution interposer, in accordance with some embodiments.

FIGS. 45 through 47 illustrate cross-sectional views of intermediate steps during a process for forming a package component, in accordance with some embodiments.

FIG. 48 illustrates a cross-sectional view of an intermediate step in the formation of a package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a redistribution interposer of a package component is formed. Each redistribution layer of the redistribution interposer is formed using a dual exposure photolithography technique that uses multiple exposures of pattern regions that overlap. In some embodiments, a first pattern region surrounds a second pattern region, and the first pattern region and the second pattern region are exposed in different exposure steps with different photolithography masks. This allows for larger areas of the redistribution interposer to be formed having finer redistribution layers, which can allow for improved functionality of larger redistribution interposers. The techniques described herein can allow for larger redistribution interposers with improved routing and reduced cost.

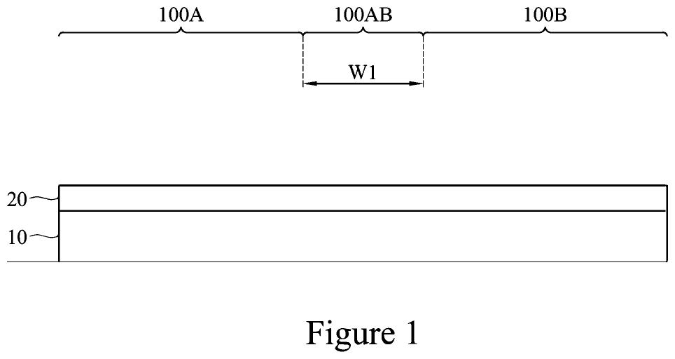

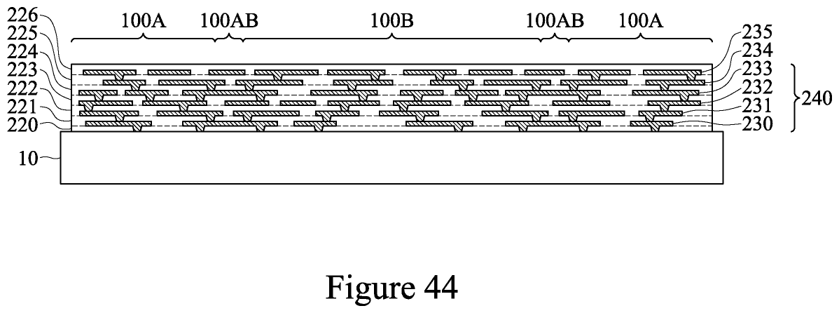

FIGS. 1 through 16 illustrate cross-sectional views and plan views of intermediate steps in the formation of a redistribution interposer, in accordance with some embodiments. The process steps shown in FIGS. 1-16 may be similar to those used to form the redistribution interposer 240 (see FIG. 44), described in greater detail below.

In FIG. 1, a carrier substrate 10 is provided, in accordance with some embodiments. The carrier substrate 10 may be a glass carrier substrate, a ceramic carrier substrate, a die attach film (DAF), or the like. The carrier substrate 10 may be a wafer or the like, such that multiple packages can be formed on the carrier substrate 10 simultaneously.

In some embodiments, a release layer (not illustrated) is formed over the carrier substrate 10. The release layer may be formed of a polymer-based material, which may be removed along with the carrier substrate 10 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer may be an ultra-violet (UV) glue, which loses its adhesive property when exposed to UV lights. The release layer may be dispensed as a liquid and cured, may be a laminate film laminated onto the carrier substrate 10, or may be the like. The top surface of the release layer may be leveled and may have a high degree of planarity.

The carrier substrate 10 includes a first pattern region 100A, a second pattern region 100B, and an overlap region 100AB. The first pattern region 100A and the second pattern region 100B are regions of the carrier substrate 10 on which lithography processes are performed in separate steps. For example, the first pattern region 100A of a photosensitive layer (e.g., a photoresist layer, photomask, or the like) may be exposed to light in a first exposure process, and the second pattern region 100B of the photosensitive layer may be exposed to light in a second exposure process. The overlap region 100AB is a region that is exposed to light in both the first exposure process (along with the first pattern region 100A) and the second exposure process (along with the second pattern region 100B). In this manner, the overlap region 100AB may be considered part of both the first pattern region 100A and the second pattern region 100B, and may be considered a “stitching region” or the like. In some embodiments, the first pattern region 100A may surround the second pattern region 100B, described in greater detail below. In this manner, the size (e.g., area or dimensions) of the first pattern region 100A may be larger than the size of the second pattern region 100B. In some embodiments, multiple second pattern regions 100B may be present, with corresponding overlap regions 100AB between the first pattern region 100A and each second pattern region 100B. In some embodiments, an overlap region 100AB may have a width W1 that is in the range of about 1 μm to about 50 μm, though other widths are possible.

Still referring to FIG. 1, a dielectric layer 20 is formed over the carrier substrate 10, in accordance with some embodiments. The dielectric layer 20 may be formed over the release layer, if present. The bottom surface of the dielectric layer 20 may be in contact with the top surface of the carrier substrate 10 or the top surface of the release layer. In some embodiments, the dielectric layer 20 is formed of a polymer, such as polybenzoxazole (PBO), polyimide, benzocyclobutene (BCB), or the like. In other embodiments, the dielectric layer 20 is formed of a nitride such as silicon nitride; an oxide such as silicon oxide, phosphosilicate glass (PSG), borosilicate glass (BSG), boron-doped phosphosilicate glass (BPSG), or the like; or the like. In other embodiments, the dielectric layer 20 may be molding compound, epoxy, or any other suitable materials. The dielectric layer 20 may be formed by any acceptable deposition process, such as spin coating, chemical vapor deposition (CVD), laminating, the like, or a combination thereof. The dielectric layer 20 may be considered a passivation layer, an insulating layer, and/or an isolation layer, in some cases. In other embodiments, a metallization pattern or other conductive features (not illustrated) may first be formed over the carrier substrate 10 and then may be covered by the dielectric layer 20.

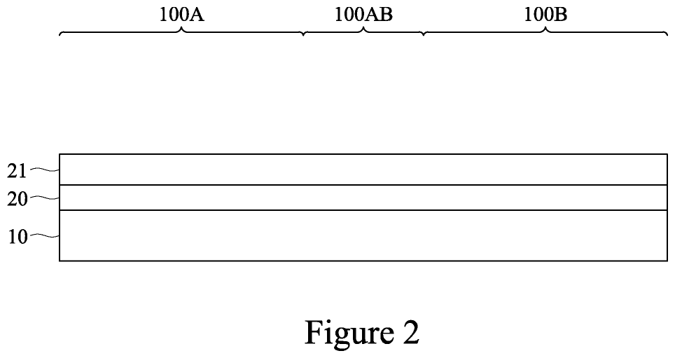

In FIG. 2, a first photoresist layer 21 is formed over the dielectric layer 20, in accordance with some embodiments. The first photoresist layer 21 may be, for example, a single layer of photoresist, a bi-layer photoresist, a tri-layer photoresist, multiple layers of different materials, a photoresist structure, or the like. Furthermore, in the subsequently discussed embodiment, it is assumed that the first photoresist layer 21 is a positive photoresist, in which the light-exposed portions are removed and un-exposed portions remain after light-exposure processes and a subsequent development process. In accordance with alternative embodiments, the first photoresist layer 21 includes a negative photoresist, in which the un-exposed portions are removed and the light-exposed portions remain after light-exposure processes and a subsequent development process. The first photoresist layer 21 may be formed using suitable techniques, such as spin coating, CVD, laminating, the like, or a combination thereof. In other embodiments in which the dielectric layer 20 is a photosensitive material that can be patterned using photolithography techniques, a first photoresist layer 21 may not be formed. In such embodiments, the dielectric layer 20 may be a photosensitive material such as PBO, polyimide, BCB, or the like.

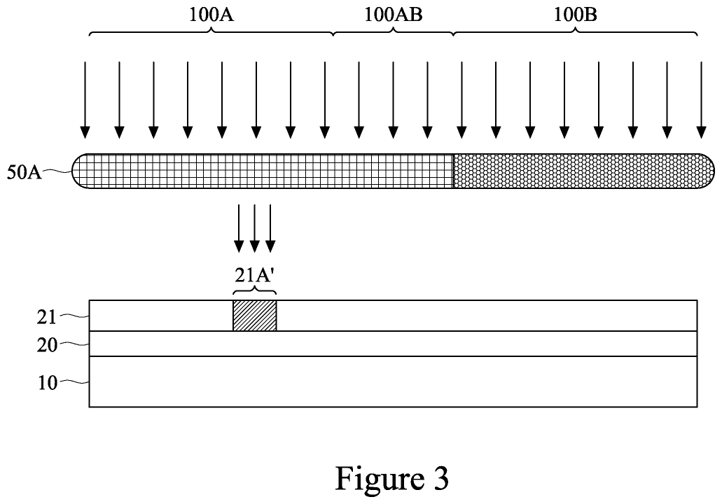

In FIG. 3, a first exposure process is performed to expose portions of the first photoresist layer 21 in the first pattern region 100A and the overlap region 100AB, in accordance with some embodiments. The first exposure process may include positioning a first photolithography mask 50A (e.g., a reticle, light mask, or the like) over the first photoresist layer 21 and exposing the first photolithography mask 50A to light (indicated by the arrows in FIG. 3). The first photolithography mask 50A includes opaque regions that block the light and transparent regions that allow transmission of the light through the first photolithography mask 50A to the first photoresist layer 21. The transparent regions of the first photolithography mask 50A correspond to the pattern of portions of the first photoresist layer 21 that are exposed to light and are subsequently removed. An example exposed portion of the first photoresist layer 21 in first pattern region 100A is indicated as exposed portion 21A′ in FIG. 3. While FIG. 3 illustrates only an exposed portion of the first photoresist layer 21 in the first pattern region 100A, portions of the first photoresist layer 21 in the overlap region 100AB may also be exposed.

Notably, the first photolithography mask 50A only exposes portions of the first photoresist layer 21 in the first pattern region 100A and the overlap region 100AB. For example, the first photolithography mask 50A may comprise a large opaque region that extends continuously over the second pattern region 100B. Thus, the second pattern region 100B of the first photoresist layer 21 is not exposed to light during the first exposure process. The size (e.g., area) of the first photolithography mask 50A may be large enough to cover the entire redistribution interposer that is subsequently formed. In some embodiments, the opaque region of the first photolithography mask 50A corresponding to the second pattern region 100B may be surrounded (e.g., laterally encircled) by transparent patterning regions of the first photolithography mask 50A corresponding to the first pattern region 100A and the overlap region 100AB.

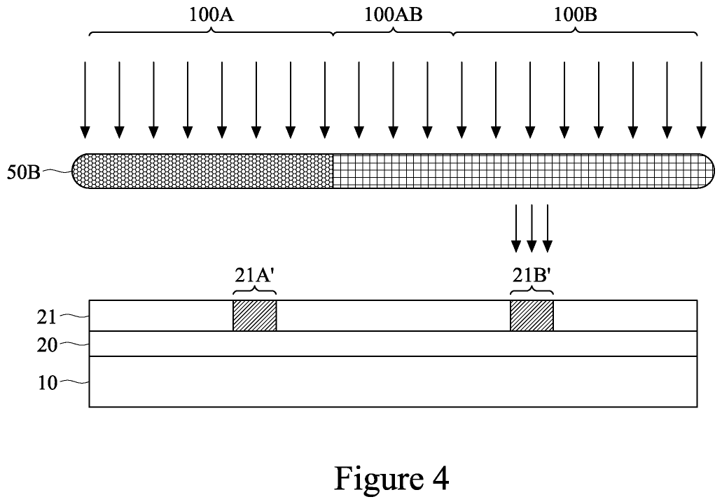

In FIG. 4, a second exposure process is performed to expose portions of the first photoresist layer 21 in the second pattern region 100B and the overlap region 100AB, in accordance with some embodiments. The second exposure process may include positioning a second photolithography mask 50B (e.g., a reticle, light mask, or the like) over the first photoresist layer 21 and exposing the second photolithography mask 50B to light (indicated by the arrows in FIG. 4). The second photolithography mask 50B includes opaque regions that block the light and transparent regions that allow transmission of the light through the second photolithography mask 50B to the first photoresist layer 21. The transparent regions of the second photolithography mask 50B correspond to the pattern of portions of the first photoresist layer 21 that are exposed to light and are subsequently removed. An example exposed portion of the first photoresist layer 21 in second pattern region 100B is indicated as exposed portion 21B′ in FIG. 4. While FIG. 4 illustrates only an exposed portion of the first photoresist layer 21 in the second pattern region 100B, portions of the first photoresist layer 21 in the overlap region 100AB may also be exposed.

Notably, the second photolithography mask 50B only exposes portions of the first photoresist layer 21 in the second pattern region 100B and the overlap region 100AB. For example, the second photolithography mask 50B may comprise an opaque region that extends continuously around the second pattern region 100B and the overlap region 100AB. Thus, the first pattern region 100A of the first photoresist layer 21 is not exposed to light during the second exposure process. In some embodiments, the same second photolithography mask 50B may be used to expose multiple second pattern regions 100B when multiple second pattern regions 100B are present. For example, the second photolithography mask 50B may expose a first second pattern region 100B, be repositioned over a second second pattern region 100B, then used to expose the second second pattern region 100B in a separate exposure process. In some embodiments, because the size of the first pattern region 100A is larger than the size of the second pattern region 100B, the size of the transparent regions of the first photolithography mask 50A may be larger than the size of the transparent regions of the second photolithography mask 50B. In some cases, the size of the first photolithography mask 50A may be larger than the size of the second photolithography mask 50B. In some embodiments, the feature size (e.g., linewidth, pitch, spacing, etc.) of the pattern of the second photolithography mask 50B is smaller than that of the first photolithography mask 50A. For example, in some embodiments, a linewidth of features of the first photolithography mask 50A may be about 5 μm, and a linewidth of features of the second photolithography mask 50B may be about 2 μm. Other linewidths are possible. FIGS. 3-4 illustrate the first exposure process using the first photolithography mask 50A and the second exposure process using the second photolithography mask 50B, but in other embodiments, the first exposure process may use the second photolithography mask 50B and the second exposure process may use the first photolithography mask 50A.

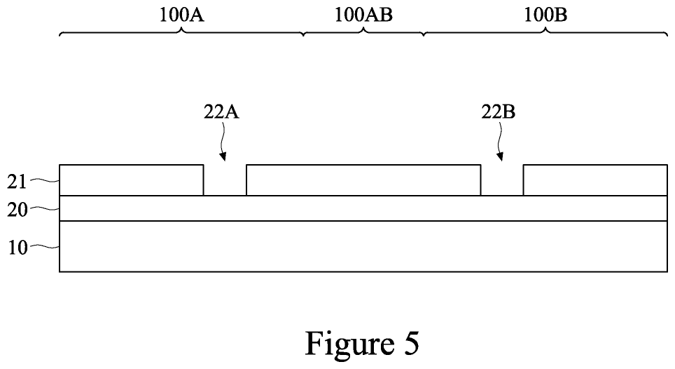

In FIG. 5, the first photoresist layer 21 is developed to form openings 22A-B, in accordance with some embodiments. The openings 22A-B expose the underlying dielectric layer 20, in some embodiments. The first photoresist layer 21 may be developed using suitable photolithographic development techniques that remove exposed portions of the first photoresist layer 21. For example, the exposed portion 21A′ is removed to form opening 22A, and the exposed portion 21B′ is removed to form opening 22B. In this manner, the first photoresist layer 21 may be patterned using a first light exposure process and a second light exposure process.

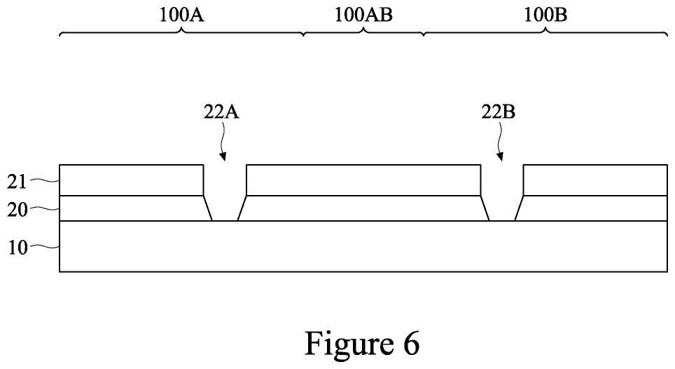

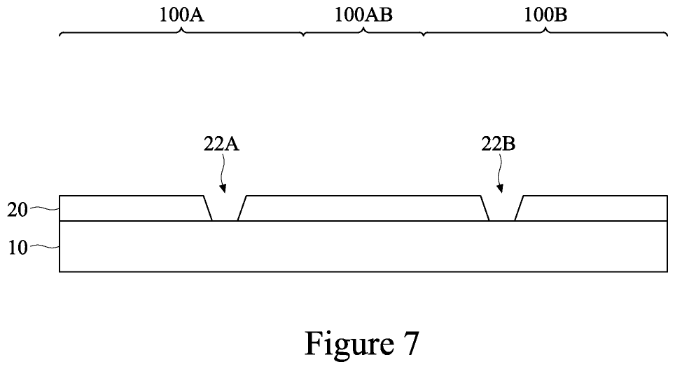

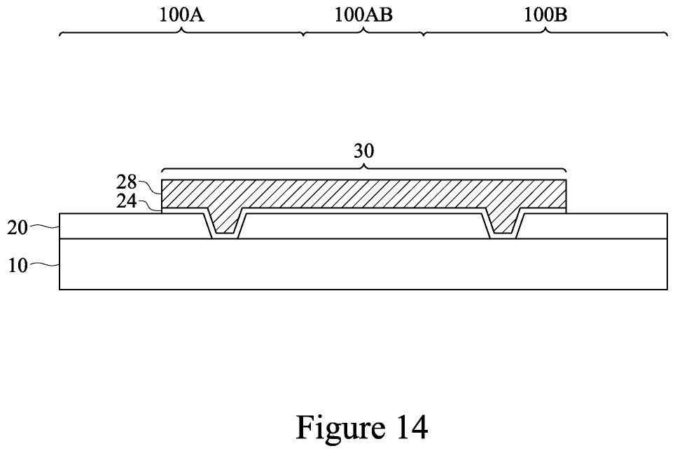

In FIG. 6, an etching process is performed to extend the openings 22A-B through the dielectric layer 20, in accordance with some embodiments. In this manner, the patterned first photoresist layer 21 may act as a etch mask. The etching process may comprise a wet etching process and/or a dry etching process, which may be anisotropic. In some embodiments, the openings 22A-B in the dielectric layer 20 correspond to via portions of the subsequently-formed redistribution layer (e.g. the redistribution layer 30 of FIG. 14). In embodiments in which a metallization pattern is first formed over the carrier substrate 10, the openings 22A-B in the dielectric layer 20 may expose the metallization pattern. After etching the dielectric layer 20, the first photoresist layer 21 may be removed, as shown in FIG. 7. The first photoresist layer 21 may be removed using an acceptable ashing or stripping process, such as using an oxygen plasma or the like.

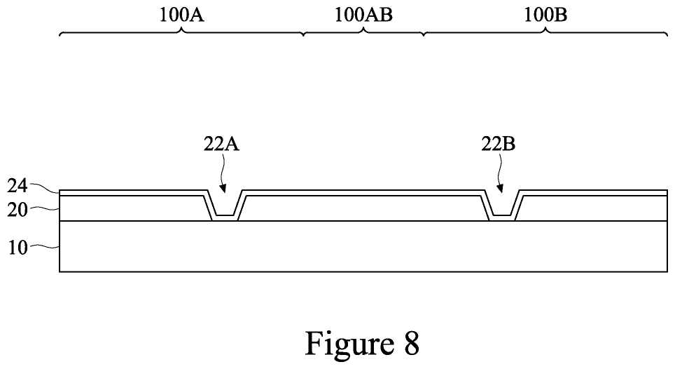

In FIG. 8, a seed layer 24 is deposited over the dielectric layer 20 and into the openings 22A-B, in accordance with some embodiments. In some embodiments, the seed layer 24 is a metal layer, which may be a single layer or a composite layer comprising a plurality of sub-layers formed of different materials. In some embodiments, the seed layer 24 comprises a titanium layer and a copper layer over the titanium layer. The seed layer 24 may be formed using, for example, physical vapor deposition (PVD) or the like. The deposition of the seed layer 24 may be conformal, in some cases.

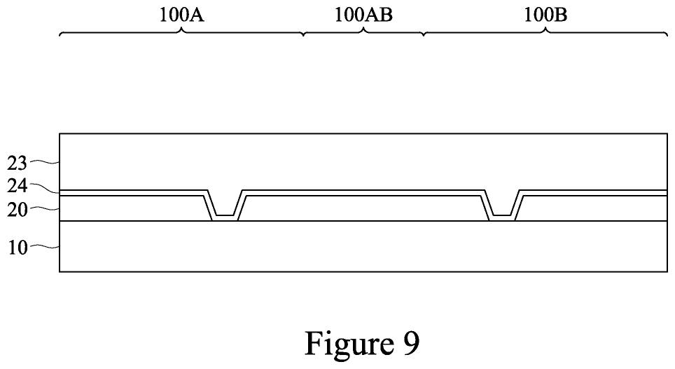

In FIG. 9, a second photoresist layer 23 is formed over the seed layer 24, in accordance with some embodiments. The second photoresist layer 23 may be similar to the first photoresist layer 21, in some cases. For example, the second photoresist layer 23 may be a single layer of photoresist, a bi-layer photoresist, a tri-layer photoresist, multiple layers of different materials, a photoresist structure, or the like. Furthermore, in the subsequently discussed embodiment, it is assumed that the second photoresist layer 23 is a positive photoresist, in which the light-exposed portions are removed and un-exposed portions remain after light-exposure processes and a subsequent development process. In accordance with alternative embodiments, the second photoresist layer 23 includes a negative photoresist, in which the un-exposed portions are removed and the light-exposed portions remain after light-exposure processes and a subsequent development process. The second photoresist layer 23 may be formed using suitable techniques, such as spin coating, CVD, laminating, the like, or a combination thereof.

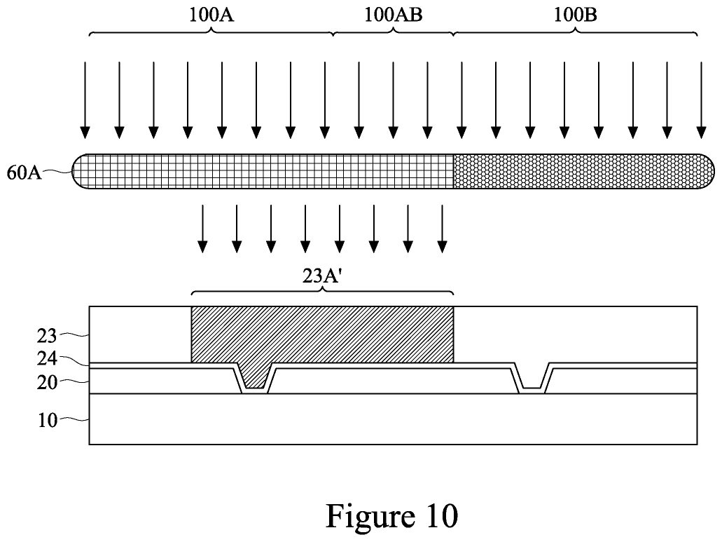

In FIG. 10, a first exposure process is performed to expose portions of the second photoresist layer 23 in the first pattern region 100A and the overlap region 100AB, in accordance with some embodiments. The first exposure process may include positioning a first photolithography mask 60A (e.g., a reticle, light mask, or the like) over the second photoresist layer 23 and exposing the first photolithography mask 60A to light (indicated by the arrows in FIG. 10). The first photolithography mask 60A is different from the first photolithography mask 50A used to pattern the first photoresist layer 21, but it may have some similar aspects. For example, transparent regions of the first photolithography mask 60A correspond to the pattern of portions of the second photoresist layer 23 that are exposed to light and are subsequently removed. An example exposed portion of the second photoresist layer 23 in first pattern region 100A and the overlap region 100AB is indicated as exposed portion 23A′ in FIG. 10.

Notably, the first photolithography mask 60A only exposes portions of the second photoresist layer 23 in the first pattern region 100A and the overlap region 100AB. For example, the first photolithography mask 60A may comprise a large opaque region that extends continuously over the second pattern region 100B. Thus, the second pattern region 100B of the second photoresist layer 23 is not exposed to light during the first exposure process. The size (e.g., area) of the first photolithography mask 60A may be large enough to cover the entire redistribution interposer that is subsequently formed. In some embodiments, the opaque region of the first photolithography mask 60A corresponding to the second pattern region 100B may be surrounded (e.g., laterally encircled) by transparent patterning regions of the first photolithography mask 60A corresponding to the first pattern region 100A and the overlap region 100AB.

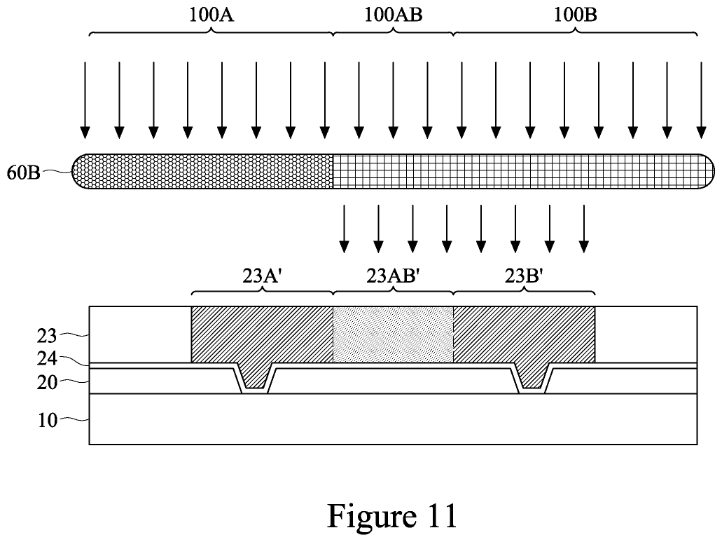

In FIG. 11, a second exposure process is performed to expose portions of the second photoresist layer 23 in the second pattern region 100B and the overlap region 100AB, in accordance with some embodiments. The second exposure process may include positioning a second photolithography mask 60B (e.g., a reticle, light mask, or the like) over the second photoresist layer 23 and exposing the second photolithography mask 60B to light (indicated by the arrows in FIG. 11). The second photolithography mask 60B includes opaque regions that block the light and transparent regions that allow transmission of the light through the second photolithography mask 60B to the second photoresist layer 23. The transparent regions of the second photolithography mask 60B correspond to the pattern of portions of the second photoresist layer 23 that are exposed to light and are subsequently removed.

An example exposed portion of the second photoresist layer 23 in second pattern region 100B is indicated as exposed portion 23B′ in FIG. 11. Further, a portion of the second photoresist layer 23 in the overlap region 100AB that was previously exposed during the first exposure process may be exposed again during the second exposure process. An example “doubly-exposed” portion of the second photoresist layer 23 is indicated as doubly-exposed portion 23AB′ in FIG. 11. Note that the doubly-exposed portion 23AB′ includes part of the exposed portion 23A′ in the overlap region 100AB. As shown in FIG. 11, the second photoresist layer 23 may have an exposed portion that extends continuously from the first pattern region 100A, through the overlap region 100AB, and into the second pattern region 100B. In this manner, exposed portions in the first pattern region 100A and exposed portions in the second pattern region 100B may be “stitched” by doubly-exposed portions in the overlap region 100AB. In some cases, a portion of the second photoresist layer 23 in the overlap region 100AB may be exposed only a single time during either the first exposure process or the second exposure process.

Notably, the second photolithography mask 60B only exposes portions of the second photoresist layer 23 in the second pattern region 100B and the overlap region 100AB. For example, the second photolithography mask 60B may comprise an opaque region that extends continuously around the second pattern region 100B and the overlap region 100AB. Thus, the first pattern region 100A of the second photoresist layer 23 is not exposed to light during the second exposure process. In some embodiments, the same second photolithography mask 60B may be used to expose multiple second pattern regions 100B when multiple second pattern regions 100B are present. For example, the second photolithography mask 60B may expose a first second pattern region 100B, be repositioned over a second second pattern region 100B, then used to expose the second second pattern region 100B in a separate exposure process. In some embodiments, because the size of the first pattern region 100A is larger than the size of the second pattern region 100B, the size of the transparent regions of the first photolithography mask 60A may be larger than the size of the transparent regions of the second photolithography mask 60B. In some cases, the size of the first photolithography mask 60A may be larger than the size of the second photolithography mask 60B. In some embodiments, the feature size (e.g., linewidth, pitch, etc.) of the pattern of the second photolithography mask 60B is smaller than that of the first photolithography mask 60A. For example, in some embodiments, a linewidth of features of the first photolithography mask 60A may be about 5 μm, and a linewidth of features of the second photolithography mask 60B may be about 2 μm. Other linewidths are possible. FIGS. 10-11 illustrate the first exposure process using the first photolithography mask 60A and the second exposure process using the second photolithography mask 60B, but in other embodiments, the first exposure process may use the second photolithography mask 60B and the second exposure process may use the first photolithography mask 60A.

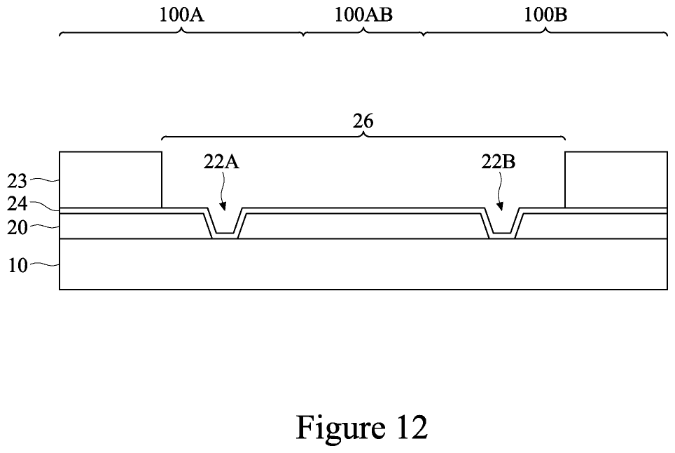

In FIG. 12, the second photoresist layer 23 is developed to form an opening 26, in accordance with some embodiments. The opening 26 exposes the seed layer 24 and includes the previously formed openings 22A-B. The opening 26 extends from the first pattern region 100A, through the overlap region 100AB, and into the second pattern region 100B. In other embodiments, openings similar to the opening 26 may be present in the first pattern region 100A, the overlap region 100AB, or the second pattern region 100B, or extend between or through one or more of these regions. The second photoresist layer 23 may be developed using suitable photolithographic development techniques that remove exposed portions of the second photoresist layer 23. For example, the exposed portions 23A′, 23AB′, and 23B′ are all removed to form the opening 26. In this manner, the second photoresist layer 23 may be patterned using a first light exposure process and a second light exposure process, and may include doubly-exposing some portions of the second photoresist layer 23.

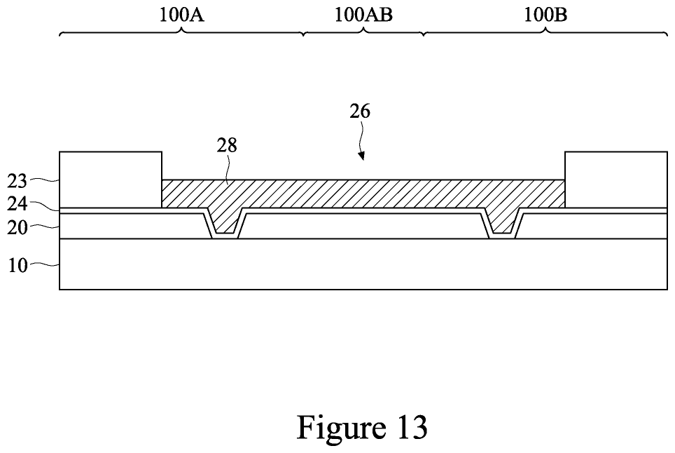

In FIG. 13, a conductive material 28 is formed on the exposed portions of the seed layer 24 in the opening 26 of the second photoresist layer 23. The conductive material 28 may be formed by CVD, physical vapor deposition (PVD), plating, (e.g., electroplating or electroless plating), or the like. The conductive material 28 may comprise a metal such as copper, titanium, tungsten, aluminum, ruthenium, cobalt, the like, or a combination thereof. Other materials are possible. In some embodiments, a thickness of the conductive material 28 may be less than a thickness of the second photoresist layer 23.

In FIG. 14, the second photoresist layer 23 and underlying portions of the seed layer 24 are removed to form a redistribution layer 30, in accordance with some embodiments. The second photoresist layer 23 may be removed using an acceptable ashing or stripping process, such as using an oxygen plasma or the like. Once the second photoresist layer 23 is removed, exposed portions of the seed layer 24 are removed using, for example, an acceptable wet or dry etching process. The remaining portions of the seed layer 24 and the conductive material 28 form the redistribution layer 30. In some embodiments, the redistribution layer 30 comprises conductive via portions that extend through the dielectric layer 20 and conductive line portions that extend along a top surface of the dielectric layer 20. In some cases, the redistribution layer 30 may be considered a redistribution line, a metallization pattern, a routing layer, or the like.

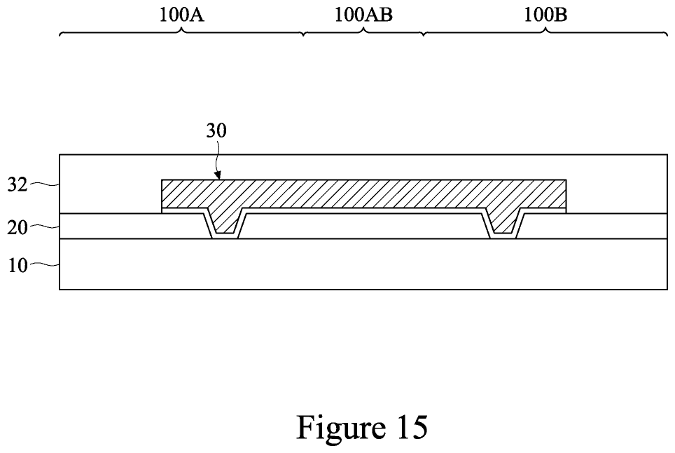

In FIG. 15, a dielectric layer 32 is formed on the redistribution layer 30 and the dielectric layer 20, in accordance with some embodiments. The dielectric layer 32 may be a material similar to the dielectric layer 20 or may be a material different from the dielectric layer 20. For example, in some embodiments, the dielectric layer 32 is formed of a polymer such as PBO, polyimide, BCB, or the like. In other embodiments, the dielectric layer 32 is formed of a nitride such as silicon nitride; an oxide such as silicon oxide, PSG, BSG, BPSG; a molding material; or the like. In some embodiments, the dielectric layer 32 is a photosensitive material such as PBO, polyimide, BCB, or the like, that may be patterned using a photolithography mask. The dielectric layer 112 may be formed by spin coating, lamination, CVD, the like, or a combination thereof.

FIG. 15 illustrates a single redistribution layer 30, but in some embodiments, processes similar to those used to form the redistribution layer 30 may be performed to form additional redistribution layers as part of a redistribution interposer or the like. In this manner, a redistribution interposer may include any number of dielectric layers and redistribution layers. If more dielectric layers and redistribution layers are to be formed, steps and processes similar to those discussed above may be repeated. For example, in some embodiments, a redistribution interposer may comprise a stack of six or more redistribution layers, though more or fewer redistribution layers are possible.

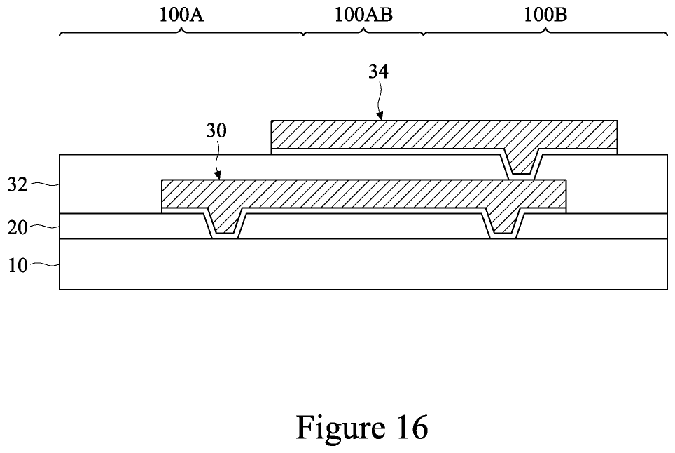

As an example, FIG. 16 illustrates an additional redistribution layer 34 formed over the redistribution layer 30, in accordance with some embodiments. The redistribution layer 34 extends across the first pattern region 100A, the overlap region 100AB, and the second pattern region 100B, and a via portion of the redistribution layer 34 extends through the dielectric layer 32 to physically and electrically connect the redistribution layer 30. Like the redistribution layer 30, the redistribution layer 34 is an illustrative example, and other arrangements or configurations are possible. The redistribution layer 34 may be formed using steps similar to those described for the redistribution layer 30. For example, a first photoresist layer may be formed over the dielectric layer 32 and patterned using two exposure processes. The patterned first photoresist layer may be used as an etch mask to form an opening through the dielectric layer 32 that exposes the redistribution layer 30. A seed layer may then be deposited over the dielectric layer 32 and in the opening. A second photoresist layer may then be formed over the seed layer and patterned using two exposure processes. A conductive material may be deposited on exposed portions of the seed layer. The second photoresist layer and underlying portions of the seed layer may then be removed, with the conductive material and remaining portions of the seed layer forming the redistribution layer 34. Further, an additional dielectric layer may be formed over the redistribution layer 34 and the dielectric layer 32, which may be similar to the dielectric layer 20 or the dielectric layer 32. Additional redistribution layers and/or dielectric layers may be similarly formed according to the functional and structural requirements of the redistribution interposer.

In some cases, a portion of a dielectric layer in a region that is doubly-exposed (e.g., exposed during both a first exposure process and a second exposure process) during patterning may form a bulge (e.g., a bump, protrusion, hump, or the like). The “bulging portion” of the dielectric layer may underlie a portion of photoresist that is exposed to light during both exposure processes (e.g., similar to doubly-exposed portion 23AB′ of FIG. 11). In some cases, a bulging portion of a dielectric layer may be a portion of the dielectric layer having a relatively large thickness. In some cases, a bulging portion of a dielectric layer may be a portion of a dielectric layer that extends over a bulging portion of an underlying dielectric layer. In some cases, a redistribution layer that extends over a bulging portion of a dielectric layer may have a corresponding bulging portion. A bulging portion of a dielectric layer or redistribution layer may have a width that is greater than, less than, or about the same as the width W1 of the overlap region 100AB.

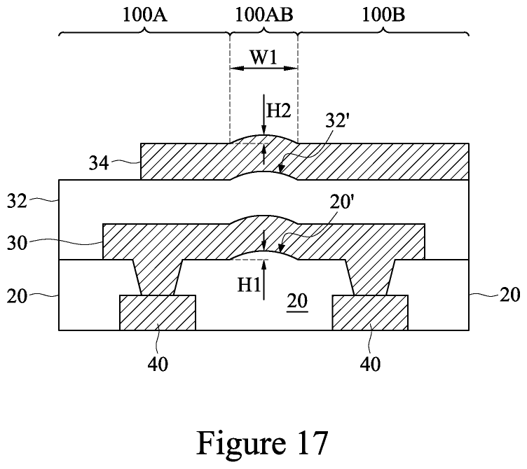

As an example, FIG. 17 illustrates an intermediate step in the formation of a redistribution interposer having dielectric layers with bulging portions, in accordance with some embodiments. The structure of FIG. 17 is similar to the structure of FIG. 16, except that the via portions of the redistribution layer 30 physically and electrically contact underlying conductive features 40. The conductive features 40 may be, for example, a metallization pattern formed on the carrier substrate 10, another previously-formed redistribution layer, or the like. For simplicity, features in FIG. 17 that are similar to features of FIG. 15 have been given similar reference numerals.

As shown in FIG. 17, the dielectric layer 20 includes a bulging portion 20′ in the overlap region 100AB, where double-exposure has occurred. The bulging portion 20′ has a height H1 above the non-bulging portions that is in the range of about 0.1 μm to about 1 μm, though other heights are possible. For example, portions of the dielectric layer 20 in the overlap region 100AB may protrude a height H1 from the top surface of the portions of the dielectric region in the first pattern region 100A and/or the second pattern region 100B. The redistribution layer 30 over the bulging portion 20′ may have a substantially constant thickness, and thus the portion of the redistribution layer 30 over the bulging portion 20′ may bulge a height H2 in the range of about 0.1 μm to about 1 μm from adjacent top surfaces of the redistribution layer 30. The dielectric layer 32 over the dielectric layer 20 may have a bulging portion 32′ due to being over the bulging portion 20′ and/or may have a bulging portion 32′ due to increased thickness from being doubly exposed. The bulging portion 32′ may bulge a distance H1, similar to the bulging portion 20′. Similarly, the redistribution layer 34 may bulge a distance H2, similar to the redistribution layer 30. These are examples, and other bulging portions of redistribution layers and/or dielectric layers are possible.

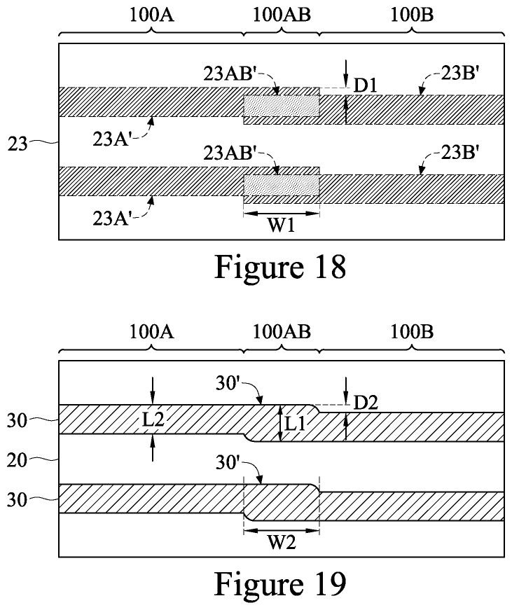

FIGS. 18 and 19 illustrate plan views of intermediate steps in the formation of a redistribution interposer, in accordance with some embodiments. FIG. 18 illustrates a plan view of a structure similar to the process step shown in FIG. 11, and FIG. 19 illustrates a plan view of a structure similar to the process step shown in FIG. 14. For simplicity, features in FIGS. 18 and 19 that are similar to features of FIGS. 11 and 19 have been given similar reference numerals. However, the structures shown in FIGS. 18-19 are illustrative examples that may apply to other process steps, such as those performed to form additional redistribution layers.

In some embodiments, a pattern in the overlap region 100AB exposed by the first exposure process matches or overlaps a corresponding pattern in the overlap region 100AB exposed by the second exposure process. However, with reference to FIG. 18, in some cases, the exposed portion 23A′ and the exposed portion 23B′ of the second photoresist layer 23 may not precisely overlap within the overlap region 100AB. An example is shown in FIG. 18, in which the exposed portions 23A′ are laterally offset by a distance D1 from the corresponding exposed portions 23B′. The offset of the exposed portions may be in any lateral direction. In some cases, the offset of the exposed portions may be due to imprecise stitching alignment between a first photolithography mask and a second photolithography mask. In some cases, the lateral offset between the exposed portions 23A′ and the exposed portions 23B′ may form singly-exposed portions in the overlap region 100AB. For example, the lateral offset of FIG. 18 causes the exposed portions 23A′ and the exposed portions 23B′ to extend into the overlap region 100AB, in addition to the doubly-exposed portion 23AB′.

With reference to FIG. 19, the lateral offset between the exposed portions 23A′ and the exposed portions 23B′ can subsequently form a redistribution layer 30 having a correspondingly offset region. An example is shown in FIG. 19, in which, due to the lateral offset D1 of FIG. 18, the redistribution layers 30 in the overlap region 100AB include kinked regions 30′ having a linewidth L1 that is larger than a linewidth L2 outside of the overlap region 100AB. These kinked regions 30′ may have a width W2 that is greater than, less than, or about the same as the width W1 of the overlap region 100AB. In some cases, the kinked regions 30′ may have a lateral offset D2 that is greater than, less than, or about the same as the lateral offset D1. In some cases, the linewidth L1 may be greater than a sum of the linewidth L2 and the lateral offset D2. In other words, the kinked regions 30′ may bulge more than shown in FIG. 19 or may have a linewidth that is greater than shown in FIG. 19. The kinked regions 30′ shown in FIG. 19 are examples, and other arrangement, configurations, or shapes are possible.

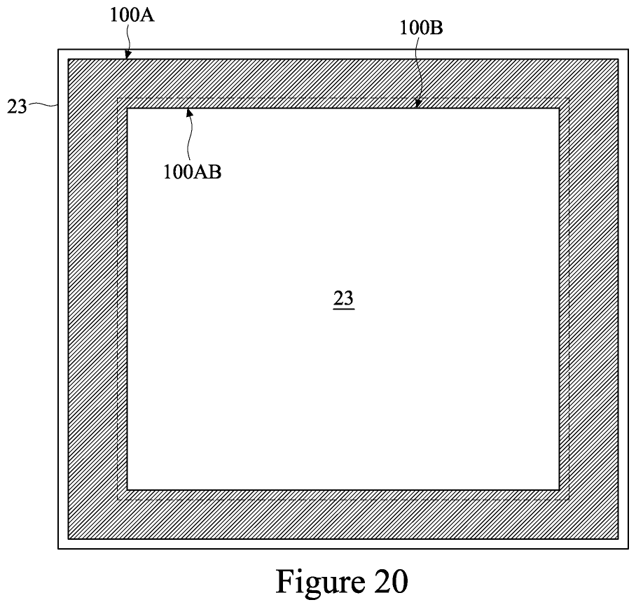

FIGS. 20 through 31 illustrate plan views of different configurations of first pattern regions 100A, second pattern regions 100B, and overlap regions 100AB, in accordance with some embodiments. FIGS. 20-31 are illustrative examples, and other arrangements or configurations are possible. FIGS. 20-31 illustrate exposed regions of a photoresist layer during the formation of a redistribution interposer, in accordance with some embodiments. The photoresist layer may be similar to the first photoresist layer 21 or the second photoresist layer 23 previously described for forming the redistribution layer 30, and for simplicity is labeled as photoresist layer 23 in FIGS. 20-31. However, it should be noted that the photoresist layer 23 of FIGS. 20-31 may be similar to other photoresist layers used to form other redistribution layers during the formation of a redistribution interposer.

FIGS. 20-31 also indicate pattern regions that may be exposed during a first exposure process or a second exposure process. For example, in FIGS. 20-31, the first pattern region 100A and the overlap region 100AB may be exposed in one light exposure process using a photolithographic mask similar to the first photolithographic mask 50A or the first photolithographic mask 60A described previously, and the second pattern region 100B and the overlap region 100AB may be exposed in a separate light exposure process using a photolithographic mask similar to the second photolithographic mask 50B or the second photolithographic mask 60B described previously. Accordingly, the first pattern region 100A, the second pattern region 100B, and the overlap region 100AB may be similar to those described previously for FIGS. 1-19. In some embodiments, multiple second pattern regions 100B may be present, described in greater detail below.

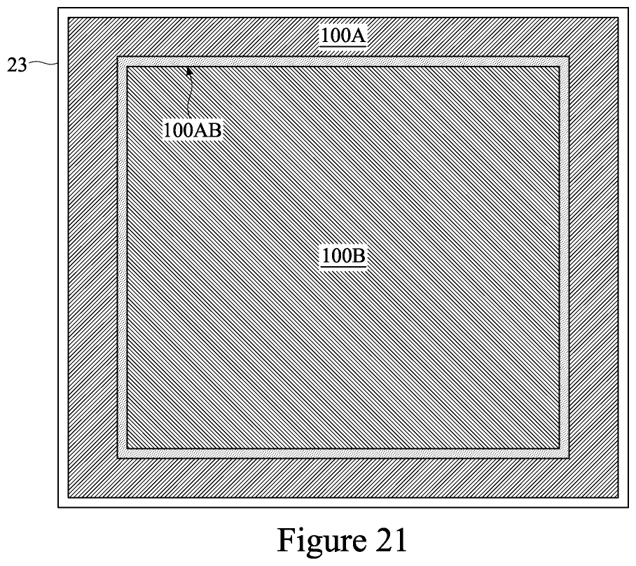

FIGS. 20 and 21 illustrate intermediate steps in the exposure of a first pattern region 100A, a second pattern region 100B, and an overlap region 100AB of the photoresist layer 23, in accordance with some embodiments. FIG. 20 illustrates the first pattern region 100A and the overlap region 100AB after performing a first exposure process. For example, the first pattern region 100A and the overlap region 100AB may be exposed using a photolithography mask, similar to the exposure using the first photolithography mask 50A of FIG. 3 or the exposure using first photolithography mask 60A of FIG. 10. The first pattern region 100A and the overlap region 100AB may have a pattern of exposed portions corresponding to the pattern of the photolithography mask, which may include exposed portions similar to the exposed portions 21A′ or 23A′, for example. As shown in FIG. 20, the second pattern region 100B is not exposed during the first exposure process. FIG. 20 shows the first pattern region 100A as having a smaller area than the photoresist layer 23, but in other embodiments, the first pattern region 100A fully covers the photoresist layer 23, and may be about the same size as or have a bigger size than the photoresist layer 23.

As shown in FIG. 20, in some embodiments, the first pattern region 100A has a ring-like shape that encircles the second pattern region 100B, and thus the exposed portion of the photoresist layer 23 encircles the unexposed portion after the first exposure process. The overlap region 100AB is between the first pattern region 100A and the second pattern region 100B, and also has a ring-like shape. In some embodiments, the first pattern region 100A may have dimensions that are about the same as or larger than the dimensions of the redistribution interposer. In some cases, using a ring-shaped first pattern region 100A allows for the use of a larger corresponding photolithography mask, which can allow for the formation a larger redistribution interposer.

FIG. 21 illustrates the second pattern region 100A and the overlap region 100AB after performing a second exposure process following the first exposure process of FIG. 20. For example, the second pattern region 100B and the overlap region 100AB may be exposed using a photolithography mask, similar to the exposure using the second photolithography mask 50B of FIG. 4 or the exposure using second photolithography mask 60B of FIG. 11. The second pattern region 100B and the overlap region 100AB may have a pattern of exposed portions corresponding to the pattern of the photolithography mask, which may include exposed portions similar to the exposed portions 21B′, 23B′, or 23AB′, for example. The first pattern region 100A is not exposed during the second exposure process. The overlap region 100AB is doubly exposed.

As shown in FIG. 21, in some embodiments, the second pattern region 100B is encircled by the first pattern region 100A and the overlap region 100AB. In some embodiments, the pattern of the second pattern region 100B has a smaller feature size than the pattern of the first pattern region 100A. The smaller size of the second pattern region 100B allows a smaller photolithography mask size to be used for the second pattern region 100B that has smaller pattern feature sizes when forming a larger redistribution interposer. By using a first exposure process to form larger feature sizes in the first pattern region 100A and a second exposure process to form smaller feature sizes in the second pattern region 100B, a large redistribution interposer may be formed that comprises flexible and efficient conductive routing. In this manner, smaller linewidth redistribution layers may be formed in the second pattern region 100B and larger linewidth redistribution layers may be formed in the first pattern region 100A, with redistribution layers in the overlap region 100AB “stitching” redistribution layers in the first pattern region 100A to redistribution layers in the second pattern region 100B.

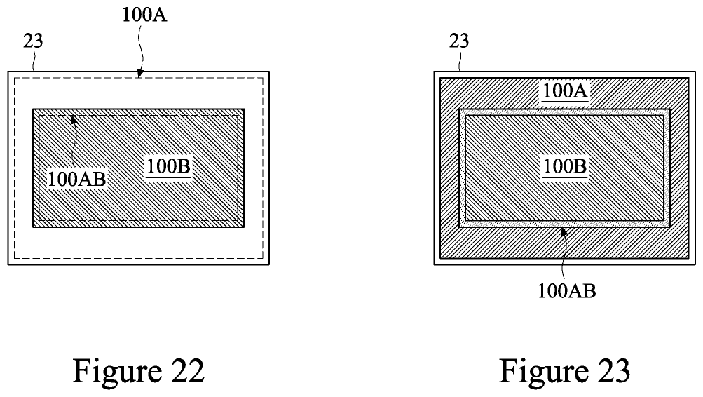

While FIGS. 20-21 illustrate the first pattern region 100A being exposed in a first exposure process before the second pattern region 100B is exposed in a second exposure process, the second pattern region 100B may be exposed before the first pattern region 100A is exposed in other embodiments. As an example, FIGS. 22-23 illustrate a first exposure process that exposes the second pattern region 100B followed by a second exposure process that exposes the first pattern region 100A, in accordance with some embodiments. In FIG. 22, a photolithography mask that blocks exposure of the first pattern region 100A and exposes a pattern in the second pattern region 100B and the overlap region 100AB is used in a first exposure process. This forms an exposed second pattern region 100B surrounded by an unexposed first pattern region 100A. In FIG. 23, a photolithography mask that blocks exposure of the second pattern region 100B and exposes a pattern in the first pattern region 100A and the overlap region 100AB is used in a second exposure process. In this manner, the photoresist layer 23 may be exposed using multiple exposure processes that expose separate regions of the photoresist layer 23.

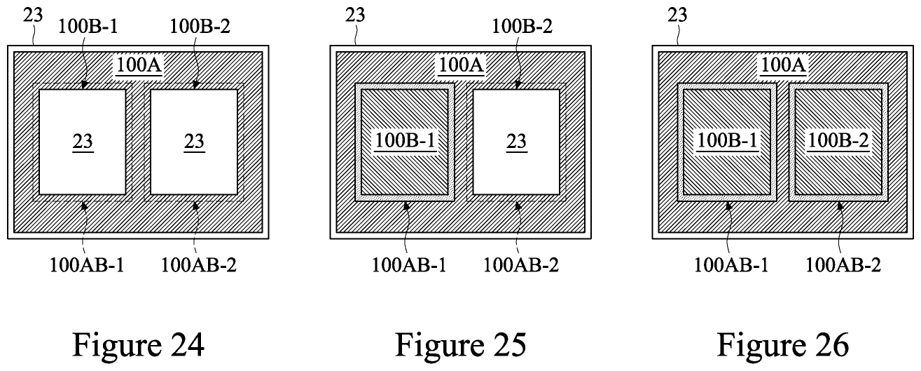

In some embodiments, the photoresist layer 23 has a plurality of second pattern regions 100B, and the same photolithographic mask is used to expose each second pattern region 100B sequentially in a corresponding plurality of exposure processes. FIGS. 24-26 illustrate intermediate steps in the exposure of a first pattern region 100A, a first second pattern region 100B-1, a first overlap region 100AB-1, a second second pattern region 100B-2, and a second overlap region 100AB-2. The first overlap region 100AB-1 is between the first second pattern region 100B-1 and the first pattern region 100A, and the second overlap region 100AB-2 is between the second second pattern region 100B-2 and the first pattern region 100A. FIGS. 24-26 illustrate an example having two second pattern regions 100B, but in other embodiments three or more second pattern regions 100B may be present. Neighboring second pattern regions 100B may be separated by the first pattern region 100A. The second pattern regions 100B may have the same size, and thus may be exposed using the same photolithographic mask. The second pattern regions 100B may have a different arrangement or configuration than shown in FIGS. 24-26.

In FIG. 24, a first exposure process is performed using a first photolithography mask to expose the first pattern region 100A, the first overlap region 100AB-1, and the second overlap region 100AB-2. The first exposure process does not expose the first second pattern region 100B-1 or the second second pattern region 100B-2. Accordingly, the first second pattern region 100B-1 and the second second pattern region 100B-2 are unexposed regions that are surrounded by the first pattern region 100A.

In FIG. 25, a second exposure process is performed using a second photolithography mask to expose the first second pattern region 100B-1 and the first overlap region 100AB-1. The second exposure process does not expose the first pattern region 100A, the second second pattern region 100B-2, or the second overlap region 100AB-2. In other embodiments, the second second pattern region 100B-2 may be exposed by the second exposure process instead of the first second pattern region 100B-1. After the second exposure process, the first overlap region 100AB-1 is doubly-exposed while the second overlap region 100AB-2 remains singly-exposed by the first exposure process only.

In FIG. 26, a third exposure process is performed using the second photolithography mask to expose the second second pattern region 100B-2 and the second overlap region 100AB-2. The third exposure process does not expose the first pattern region 100A, the first second pattern region 100B-1, or the first overlap region 100AB-1. In this manner, exposing multiple regions using the same photolithography mask can allow for larger redistribution interposers, reduced cost, and denser conductive features in the multiple regions.

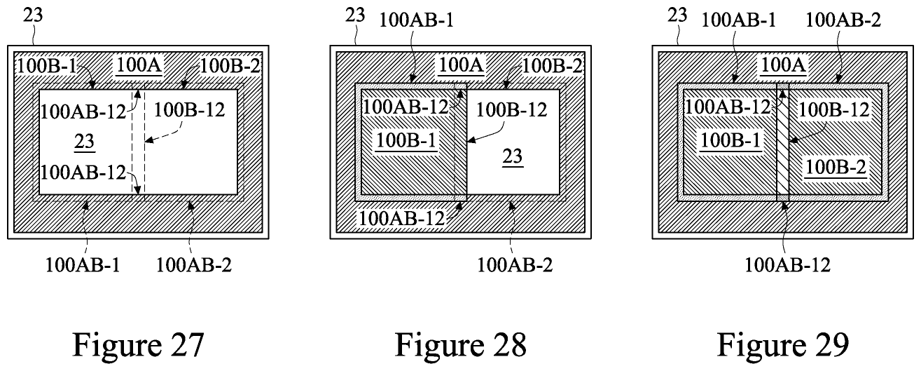

In some embodiments, the photoresist layer 23 has a plurality of second pattern regions 100B, and the exposed portions for adjacent second pattern regions 100B are overlapping, forming doubly-exposed portions between the adjacent second pattern regions 100B. As an example, FIGS. 27-29 illustrate intermediate steps in the exposure of a first pattern region 100A, a first second pattern region 100B-1, a first overlap region 100AB-1, a second second pattern region 100B-2, a second overlap region 100AB-2, an overlap region 100B-12, and overlap regions 100AB-12. The first overlap region 100AB-1 is between the first second pattern region 100B-1 and the first pattern region 100A, and the second overlap region 100AB-2 is between the second second pattern region 100B-2 and the first pattern region 100A. The overlap region 100B-12 is a doubly-exposed region between the first second pattern region 100B-1 and the second second pattern region 100B-2. The overlap regions 100AB-12 are regions that may be exposed three times, and are regions adjacent to the first pattern region 100A, the first second pattern region 100B-1, and the second second pattern region 100B-2. FIGS. 27-29 illustrate an example having two second pattern regions 100B, but in other embodiments three or more second pattern regions 100B may be present. Neighboring second pattern regions 100B may be separated by overlap regions similar to the overlap regions 100B-12. The second pattern regions 100B may have the same size, and thus may be exposed using the same photolithographic mask. The second pattern regions 100B may have a different arrangement or configuration than shown in FIGS. 27-29.

In FIG. 27, a first exposure process is performed using a first photolithography mask to expose the first pattern region 100A, the first overlap region 100AB-1, the second overlap region 100AB-2, and the overlap regions 100AB-12. The first exposure process does not expose the first second pattern region 100B-1, the second second pattern region 100B-2, or the overlap region 100B-12. Accordingly, the first second pattern region 100B-1 and the second second pattern region 100B-2 are unexposed regions that are collectively surrounded by the first pattern region 100A.

In FIG. 28, a second exposure process is performed using a second photolithography mask to expose the first second pattern region 100B-1, the first overlap region 100AB-1, the overlap region 100B-12, and the overlap regions 100AB-12. After the second exposure process, the first overlap region 100AB-1 and the overlap regions 100AB-12 are doubly-exposed, and the second second pattern region 100B-12 is unexposed.

In FIG. 29, a third exposure process is performed using the second photolithography mask to expose the second second pattern region 100B-2, the second overlap region 100AB-2, the overlap region 100B-12, and the overlap regions 100AB-12. After the second exposure process, the second overlap region 100AB-2 and the overlap region 100B-12 are doubly-exposed, and the overlap regions 100AB-12 have been exposed three times. Overlapping the exposures of the second pattern regions 100B can allow for larger redistribution interposers and larger regions of smaller conductive features within the redistribution interposers.

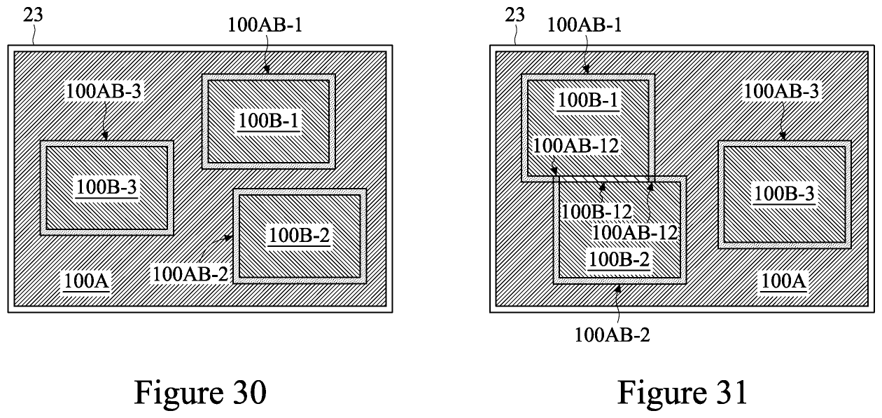

The second pattern regions 100B described for FIGS. 20-29 are examples, and any suitable configuration of second pattern regions 100B may be used in other embodiments. FIGS. 30 and 31 illustrate additional example arrangements of second pattern regions 100B, in accordance with some embodiments. FIG. 30 illustrates an arrangement of second pattern regions 100B in which edges of the second pattern regions 100B are not aligned. FIG. 30 illustrates an embodiment of second pattern regions 100B in which some of the exposures of the second pattern regions 100B overlap, similar to FIG. 29. Other arrangements, tilings, overlaps, or numbers of second pattern regions 100B are possible. The various second pattern regions 100B have corresponding overlap regions and are surrounded either individually or collectively by the first pattern region 100A.

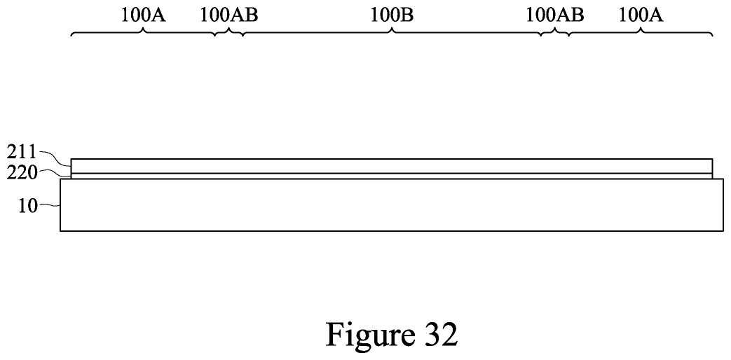

FIGS. 32 through 47 illustrate intermediate steps in the formation of a package component 200 comprising a redistribution interposer 240, in accordance with some embodiments. FIGS. 32 through 44 illustrate intermediate steps in the formation of the redistribution interposer 240, in accordance with some embodiments. The redistribution interposer 240 may be formed using steps, materials, configurations, or techniques described previously for FIGS. 1-32, and some details may not be repeated below. For example, as described below, the redistribution interposer 240 may be formed by forming a plurality of redistribution layers 230-235, wherein each redistribution layer 230-235 is formed using a plurality of exposure processes in a first pattern region 100A, a second pattern region 100B, and an overlap region 100AB. The redistribution interposer 240 is shown having six redistribution layers 230-235, but more or fewer redistribution layers may be formed in other embodiments. The illustrated redistribution interposer 240 is an example, and other configurations are possible. In some cases, using a redistribution interposer rather than another type of interposer can allow for improved density or flexibility of electrical routing, smaller package size, or reduced manufacturing cost. In some cases, the use of multiple pattern regions as described herein can allow for larger redistribution interposers to be formed. In some cases, the package component 200 may itself be considered a package.

FIG. 32 illustrates a dielectric layer 220 formed on a carrier substrate 10, and a first photoresist layer 211 formed over the dielectric layer 220, in accordance with some embodiments. The carrier substrate 10 may be similar to the carrier substrate 10 described previously. The dielectric layer 220 may be similar to the dielectric layer 20 described previously and may be formed using similar techniques. For example, the dielectric layer 220 may comprise a polymer or the like, in some embodiments. The first photoresist layer 211 may be similar to the first photoresist layer 21 described previously, and may be formed using similar techniques. In the following description, the first photoresist layer 211 is assumed to be a positive photoresist, but in other embodiments the first photoresist layer 211 may be a negative photoresist. In some embodiments, a release layer (not illustrated) may be formed on the carrier substrate 10 prior to forming the dielectric layer 220. In some embodiments, a metallization pattern (not illustrated) may be formed over the carrier substrate 10 prior to forming the dielectric layer 220. The metallization pattern may comprise, for example, conductive pads, conductive routing, or the like, and may be formed using techniques similar to those used for forming the redistribution layers 230-235.

As shown in FIG. 32, the carrier 10 and overlying layers have a first pattern region 100A, a second pattern region 100B, and an overlap region 100AB. The first pattern region 100A surrounds the second pattern region 100B and may be larger than the second pattern region 100B. The overlap region 100AB borders the second pattern region 100B and separates the second pattern region 100B from the first pattern region 100A. In other embodiments, multiple second pattern regions 100B may be present.

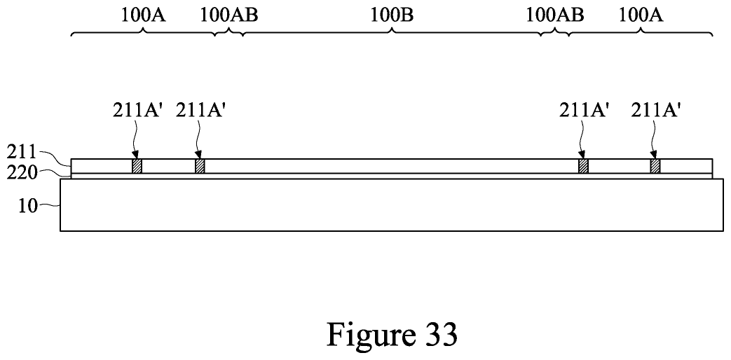

In FIG. 33, the first photoresist layer 211 is exposed in a first exposure process to form exposed portions 211A′ of the first photoresist layer 211, in accordance with some embodiments. The first exposure process may also expose portions of the first photoresist layer 211 in the overlap region 100AB. The first exposure process may be similar to that described previously for FIG. 3. For example, the first exposure process may use a first photolithographic mask (not illustrated) to expose a pattern in the first pattern region 100A and/or the overlap region 100AB. Example exposed portions 211A′ of the first photoresist layer 211 in the first pattern region 100A are illustrated in FIG. 33.

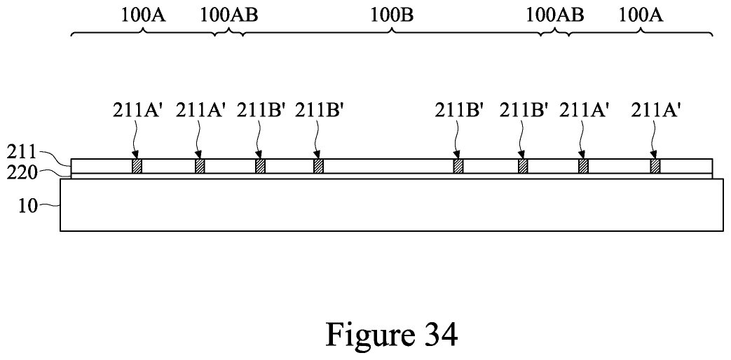

In FIG. 34, the first photoresist layer 211 is exposed in a second exposure process to form exposed portions 211B′ of the first photoresist layer 211, in accordance with some embodiments. The second exposure process may also expose portions of the first photoresist layer 211 in the overlap region 100AB, which may doubly-expose some portions in the overlap region 100AB. The second exposure process may be similar to that described previously for FIG. 4. For example, the second exposure process may use a second photolithographic mask (not illustrated) to expose a pattern in the second pattern region 100B and/or the overlap region 100AB. Example exposed portions 211B′ of the first photoresist layer 211 in the second pattern region 100B are illustrated in FIG. 34. In other embodiments, the second pattern region 100B is exposed in the first exposure process and the first pattern region 100A is exposed in the second exposure process. In other embodiments in which multiple second pattern regions 100B are present, additional exposure processes may be performed using the second photolithographic mask. The second photolithographic mask may be smaller than the first photolithographic mask, in some embodiments.

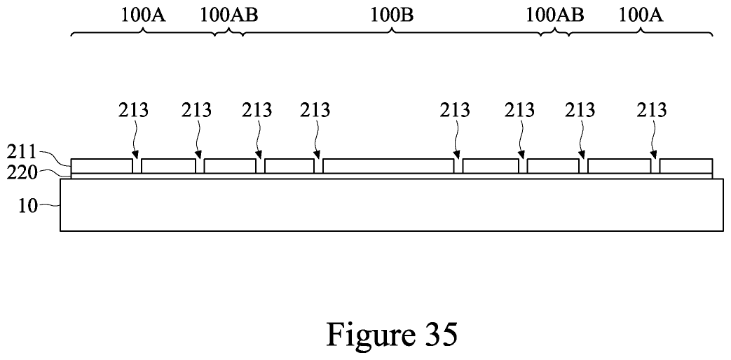

In FIG. 35, the exposed portions 211A′ and 211B′ of the first photoresist layer 211 are removed in a developing process, in accordance with some embodiments. The developing process may be similar to that described previously for FIG. 5. Developing the first photoresist layer 211 forms openings 213 that expose the underlying dielectric layer 220. In this manner, the patterning of the first photoresist layer 211 may include multiple exposure process steps but a single developing process step. For example, the patterning of first photoresist layer 211 may include exposing the first pattern region 100A and the second pattern region 100B separately, but developing the first pattern region 110A and the second pattern region 100B simultaneously. The developing process may also remove any doubly-exposed portions of the first photoresist layer 211 which may be present in the overlap region 100AB.

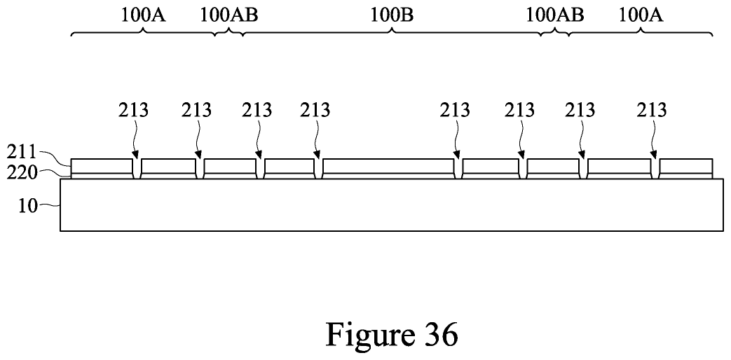

In FIG. 36, an etching process is performed to extend the openings 213 into the dielectric layer 220, in accordance with some embodiments. The etching process may be similar to the process described previously for FIG. 6. For example, the etching process may be an anisotropic dry etching process, in some embodiments. After the etching process, the openings 213 may extend fully through the dielectric layer 220. In embodiments in which a metallization pattern was previously formed, the openings 213 may expose the metallization pattern. After etching the dielectric layer 220, the first photoresist layer 211 may be removed using a process similar to that described previously for FIG. 7, such as using an ashing process or the like. In this manner, the dielectric layer 220 may be patterned.

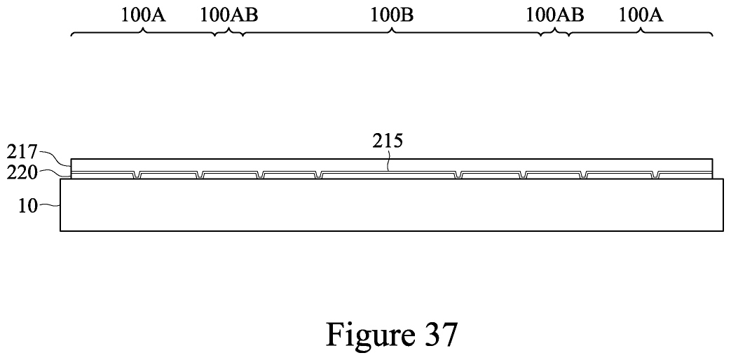

In FIG. 37, a seed layer 215 and a second photoresist layer 217 are formed over the patterned dielectric layer 220, in accordance with some embodiments. The seed layer 215 is shown in FIG. 37 but is omitted from subsequent figures for clarity. The seed layer 215 may be similar to the seed layer 24 described previously for FIG. 8, and may be formed using similar techniques. For example, in some embodiments, the seed layer 215 comprises a titanium layer and a copper layer over the titanium layer. The second photoresist layer 217 is formed over the seed layer 215, and may be similar to the second photoresist layer 23 described previously for FIG. 9. In the following description, the second photoresist layer 217 is assumed to be a positive photoresist, but in other embodiments the second photoresist layer 217 may be a negative photoresist.

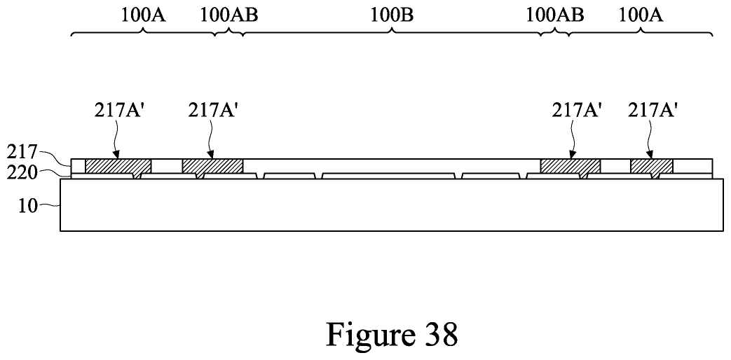

In FIG. 38, the second photoresist layer 217 is exposed in a first exposure process to form exposed portions 217A′ of the first photoresist layer 211, in accordance with some embodiments. The first exposure process may also expose portions of the second photoresist layer 217 in the overlap region 100AB. The first exposure process may be similar to that described previously for FIG. 10. For example, the first exposure process may use a first photolithographic mask (not illustrated) to exposes a pattern in the first pattern region 100A and/or the overlap region 100AB. Example exposed portions 217A′ of the second photoresist layer 217 in the first pattern region 100A and the overlap region 100AB are illustrated in FIG. 38. As shown in FIG. 38, some exposed portions 217A′ may extend from the first pattern region 100A into the overlap region 100AB.

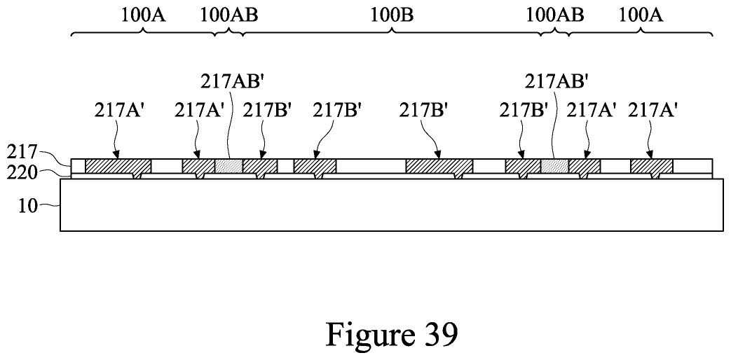

In FIG. 39, the second photoresist layer 217 is exposed in a second exposure process to form exposed portions 217B′ of the first photoresist layer 211, in accordance with some embodiments. The second exposure process may also expose portions of the second photoresist layer 217 in the overlap region 100AB. Exposing portions of the second photoresist layer 217 in the overlap region 100AB may expose previously-exposed portions 217A′ to form doubly-exposed portions 217AB′ of the second photoresist layer 217 in the overlap region 100AB. The second exposure process may be similar to that described previously for FIG. 11. For example, the second exposure process may use a second photolithographic mask (not illustrated) to expose a pattern in the second pattern region 100B and/or the overlap region 100AB. Example exposed portions 217B′ of the first photoresist layer 217 in the second pattern region 100B and doubly-exposed portions 217AB′ in the overlap region 100AB are illustrated in FIG. 39. In other embodiments, the second pattern region 100B is exposed in the first exposure process and the first pattern region 100A is exposed in the second exposure process. In other embodiments in which multiple second pattern regions 100B are present, additional exposure processes may be performed using the second photolithographic mask. The second photolithographic mask may be smaller than the first photolithographic mask, in some embodiments.

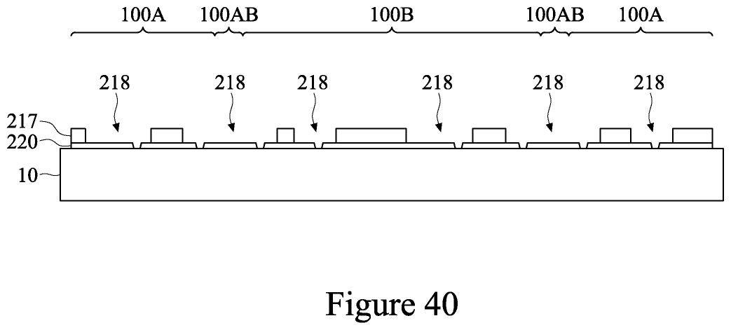

In FIG. 40, the exposed portions 217A′, the exposed portions 217B′, and the doubly-exposed portions 217AB′ of the second photoresist layer 217 are removed in a developing process, in accordance with some embodiments. The developing process may be similar to that described previously for FIG. 12. Developing the second photoresist layer 217 forms openings 218 that expose the underlying seed layer 215 (not shown in FIG. 40). In this manner, the patterning of the second photoresist layer 217 may include multiple exposure process steps but a single developing process step. For example, the patterning of second photoresist layer 217 may include exposing the first pattern region 100A and the second pattern region 100B separately, but developing the first pattern region 110A and the second pattern region 100B simultaneously.

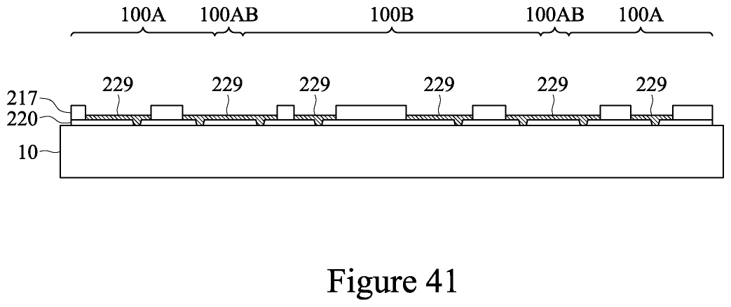

In FIG. 41, a conductive material 229 is formed on the exposed portions of the seed layer 215 in the openings 218 of the second photoresist layer 217. The conductive material 229 may be similar to the conductive material 28 described previously for FIG. 13. For example, the conductive material 229 may be formed by CVD, PVD, plating, or the like, and may comprise a metal such as copper, titanium, tungsten, aluminum, ruthenium, cobalt, the like, or a combination thereof. Other materials are possible. In some embodiments, a thickness of the conductive material 229 may be less than a thickness of the second photoresist layer 217.

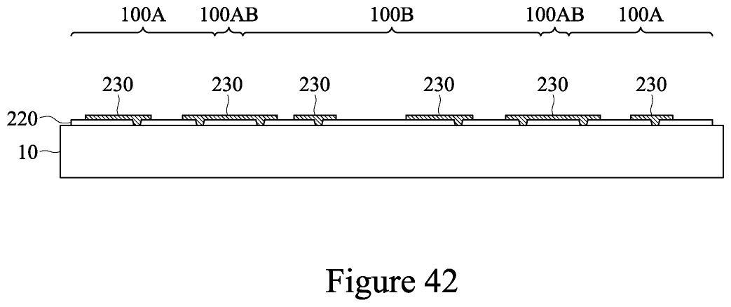

In FIG. 42, the second photoresist layer 217 and underlying portions of the seed layer 215 are removed to form a redistribution layer 230, in accordance with some embodiments. The second photoresist layer 217 may be removed using an acceptable ashing or stripping process, such as using an oxygen plasma or the like. Once the second photoresist layer 217 is removed, exposed portions of the seed layer 215 are removed using, for example, an acceptable wet or dry etching process. The remaining portions of the seed layer 215 and the conductive material 229 form the redistribution layer 230. In some embodiments, the redistribution layer 230 comprises conductive via portions that extend through the dielectric layer 220 and conductive line portions that extend along a top surface of the dielectric layer 220. In some cases, the redistribution layer 30 may be considered a redistribution line, a metallization pattern, a routing layer, or the like.

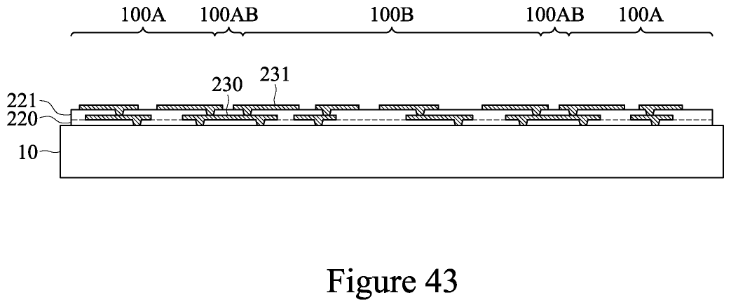

In FIG. 43, an additional dielectric layer 221 and an additional redistribution layer 231 are formed over the redistribution layer 230, in accordance with some embodiments. The dielectric layer 221 and redistribution layer 231 may be formed using techniques similar to those described above for forming the dielectric layer 220 and/or the redistribution layer 230. For example, the dielectric layer 221 may be deposited over the dielectric layer 220 and redistribution layer 230. The dielectric layer 221 may be patterned using multiple exposure processes for the pattern regions 100A-B and a developing process on a photoresist layer, followed by an etching process. A seed layer and a photoresist layer may be deposited over the patterned dielectric layer 221. The photoresist layer may be patterned using multiple exposure processes for the pattern regions 100A-B and a developing process. A conductive material may be deposited on exposed portions of the seed layer, and then the photoresist and underlying portions of the seed layer may be removed. The remaining portions of the seed layer and conductive material form the redistribution layer 231.

In FIG. 44, additional dielectric layers 222-226 and additional redistribution layers 232-235 are formed to form the redistribution interposer 240, in accordance with some embodiments. The additional dielectric layers 222-226 and redistribution layers 232-235 may be formed using steps and processes similar to those described for forming the dielectric layers 220-221 and redistribution layers 230-231. The steps and processes may be performed a larger or smaller number of times to form a larger or smaller number of additional dielectric layers and redistribution layers. In the embodiment shown in FIG. 44, the top-most redistribution layer 235 is covered by a top-most dielectric layer 226, but in other embodiments the top-most redistribution layer is not covered by the top-most dielectric layer. Due to the multiple exposure processes for patterning the first process region 100A and the second process region 100B, a size (e.g., linewidth, pitch, etc.) of the portions of the redistribution layers in the second pattern region 100B of the redistribution interposer 240 may be smaller than a size (e.g., linewidth, pitch, etc.) of the portions of the redistribution layers in the first pattern region 100A of the redistribution interposer 240.

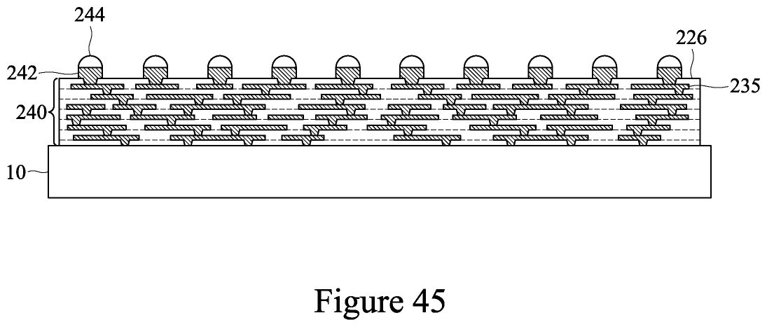

In FIG. 45, UBMs 242 are formed for external connection to the redistribution interposer 240, in accordance with some embodiments. The UBMs 242 have bump portions on and extending along the major surface of the top-most dielectric layer 226 of the redistribution interposer 240, and have via portions extending through the dielectric layer 226 to physically and electrically couple the top-most redistribution layer 235. As a result, the UBMs 242 are electrically coupled to the redistribution interposer 240. The UBMs 242 may be formed of the same material as the redistribution layers 230-235 or a different material. In some embodiments, the UBMs 242 have a different size than the redistribution layers 230-235. In other embodiments, UBMs 242 are not formed.

Still referring to FIG. 45, conductive connectors 244 are formed on the UBMs 242, in some embodiments. The conductive connectors 244 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 244 may include a conductive material such as solder, copper, aluminum, gold, nickel, silver, palladium, tin, the like, or a combination thereof. In some embodiments, the conductive connectors 244 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 244 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin—lead, gold, silver, palladium, indium, nickel—palladium—gold, nickel—gold, the like, or a combination thereof and may be formed by a plating process. In other embodiments, conductive connectors 244 are not formed.

In some embodiments, integrated passive devices (not illustrated) are attached to the redistribution interposer 240. The integrated passive devices may be attached to the UBMs 242 or to the conductive connectors 244, for example. The integrated passive devices may be semiconductor dies, chips, chiplets, surface mount devices, or the like. The integrated passive devices may comprise passive components such as resistors, capacitors, inductors, or the like. These are examples, and other integrated passive devices are possible.

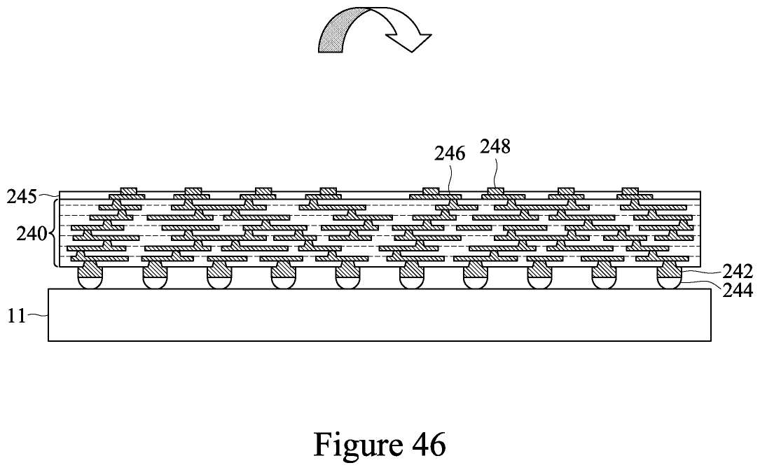

In FIG. 46, a carrier substrate de-bonding is performed to detach (or “de-bond”) the carrier substrate 10 from the redistribution interposer 240. In accordance with some embodiments, the de-bonding includes projecting a light such as a laser light or an UV light on a release layer so that the release layer decomposes under the heat of the light and the carrier substrate 10 can be removed. The carrier substrate 10 may be removed using other techniques, such as using a chemical mechanical polish (CMP) process, a grinding process, an etching process, the like, or a combination thereof. The redistribution interposer 240 is then flipped over and placed on a different carrier substrate 11, in accordance with some embodiments. The carrier substrate 11 may be similar to the carrier substrate 10, or may be a tape, die attach film (DAF), or the like.

Still referring to FIG. 46, a metallization pattern 246 and conductive pads 248 may be formed over the redistribution interposer 240, in accordance with some embodiments. In some embodiments, metallization pattern 246 may be formed over the dielectric layer 220 and the redistribution layer 230, with portions extending along a surface of the dielectric layer 220. In this manner, the metallization pattern 246 is physically and electrically connected to the redistribution interposer 240. The metallization pattern 246 may be formed using techniques similar to those used to form the redistribution layers 230-235. For example, a seed layer may be formed, a patterned photoresist may be formed over the seed layer, and a conductive material may be formed over exposed portions of the seed layer. Other techniques are possible. In other embodiments, the conductive pads 248 may be formed directly on the redistribution interposer 240 without the metallization pattern 246. In other embodiments, a metallization pattern is previously formed over the carrier substrate 10 as described previously, and so the metallization pattern 246 is not formed.

Referring still to FIG. 46, an insulating layer 245 may be deposited over the redistribution interposer 240 and the metallization pattern 245. The insulating layer 245 may be a passivation layer, a dielectric layer, or the like, and may be similar to the dielectric layers 220-226. For example, the insulating layer 245 may be any suitable insulating material such as PBO, polyimide, BCB, or the like, and in some embodiments may be a material that can be patterned using a photolithography mask. In other embodiments, the insulating layer 245 is formed of a nitride such as silicon nitride; an oxide such as silicon oxide, PSG, BSG, BPSG; or the like. The insulating layer 245 may be formed by spin coating, lamination, CVD, the like, or a combination thereof. The insulating layer 245 is then patterned using suitable photolithography techniques to form openings exposing portions of the metallization pattern 246.

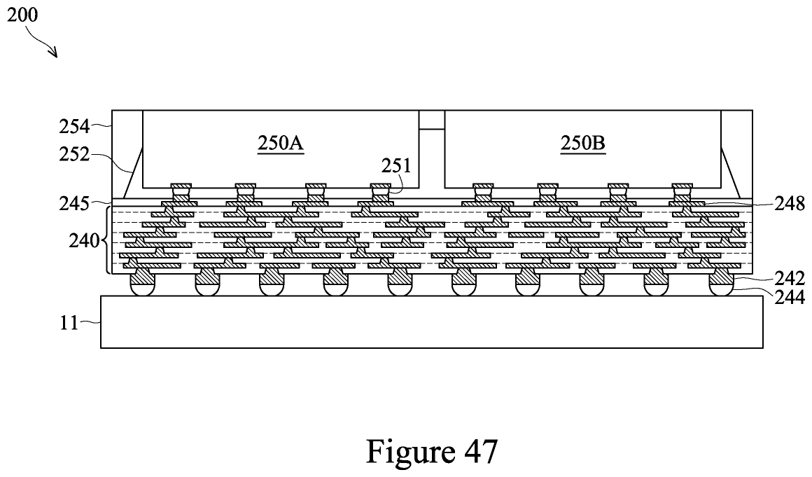

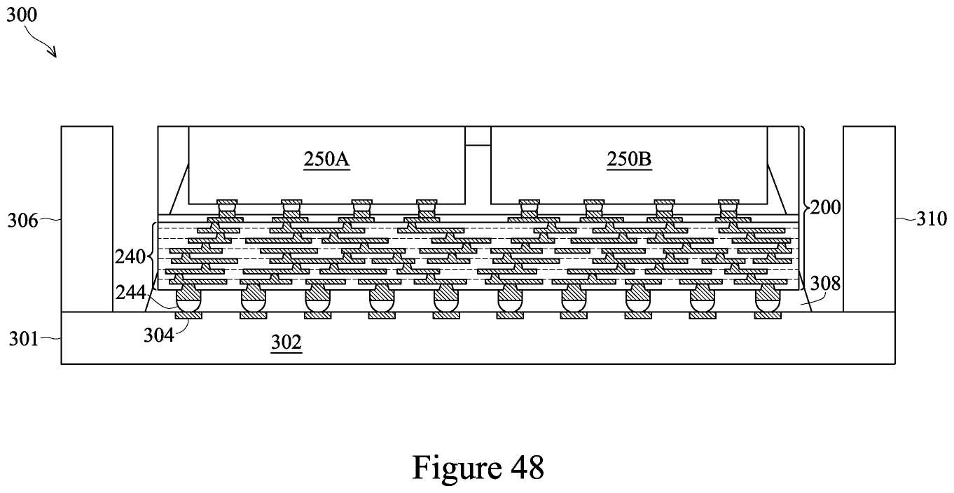

In some embodiments, conductive pads 248 are then formed on the exposed portions of the metallization pattern 246. The conductive pads 248 may be metal pads, conductive pillars, or other conductive structures that allow semiconductor devices (e.g., semiconductor devices 250A-B of FIG. 47) to be connected to the redistribution interposer 240. The conductive pads 248 may be a material similar to those of the redistribution layers 230-235, the UBMs 242, or another material. In some embodiments, the conductive pads 248 may be UBMs or the like. The conductive pads 248 may be formed on the redistribution interposer 240 in embodiments in which the metallization pattern 246 is not formed. In some embodiments, multiple redistribution interposers 240 may be formed as a single structure and then singulated into separate structures. The singulation may be performed after before or after forming the conductive pads 248.

In FIG. 47, semiconductor devices 250A-B are connected to the redistribution interposer 240 to form a package component 200, in accordance with some embodiments. The semiconductor devices 250A-B may be integrated circuit devices, semiconductor dies, chips, chiplets, packages, or the like. For example, the semiconductor devices 250A-B may include a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. In some embodiments, the semiconductor devices 250A-B include a stacked device that includes multiple semiconductor substrates 52. For example, the semiconductor devices 250A-B may include a memory device such as a hybrid memory cube (HMC) module, a high bandwidth memory (HBM) module, or the like that includes multiple memory dies. Other types of semiconductor devices are possible. The semiconductor devices 50A-B may be similar or different types of devices, and the sizes, arrangement, or number of semiconductor devices may be different than shown.

The semiconductor devices 250A-B may be bonded to the redistribution interposer 240 by conductive connectors 251. The conductive connectors 251 may be similar to the conductive connectors 244 described previously. For example, conductive connectors 251 may be formed on the semiconductor devices 250A-B. The conductive connectors 251 may be placed on the conductive pads 248, and a reflow process may be performed to bond the semiconductor devices 250A-B to the conductive pads 248. In this manner, the semiconductor devices 250A-B are physically and electrically connected to the redistribution interposer 240.

After the semiconductor devices 250A-B are bonded to the conductive pads 248, an optional underfill 252 may be deposited under the semiconductor devices 250A-B, between the semiconductor devices 250A-B and the redistribution interposer 240, and around the conductive connectors 251. In some embodiments, the underfill 252 may extend upward between the semiconductor devices 250A-B, even to the upper surfaces of the semiconductor devices 250A-B. The underfill 252 may reduce stress and protect the joints resulting from the reflowing of the conductive connectors 251. The underfill 252 may be formed by a capillary flow process after the semiconductor devices 250A-B are attached, or may be formed by a suitable deposition method before the semiconductor devices 250A-B are attached.

After the optional underfill 252 is deposited, an encapsulant 254 may be deposited over the redistribution interposer 240 and the semiconductor devices 250A-B. The encapsulant 254 may be a molding compound, epoxy, or the like. The encapsulant 254 may be applied using a suitable technique such as compression molding, transfer molding, or the like. The encapsulant 254 may be applied in liquid or semi-liquid form and then subsequently cured. In some embodiments, the encapsulant 254 may be deposited to a thickness so as to completely cover the semiconductor devices 250A-B. A planarization process, such as a CMP process, may be used to level the upper surfaces of the encapsulant 254 with the upper surfaces of the semiconductor devices 250A-B. In some embodiments, the semiconductor devices 250A-B may be thinned by the planarization process. In some embodiments, the underfill 252 may be omitted and the encapsulant 254 may function both as the underfill 252 and the encapsulant 254. In this manner, a package component 200 comprising a redistribution interposer 240 may be formed, in accordance with some embodiments. The package components 200 may be formed as a single structure that is singulated into individual package components 200, in some embodiments.

Each singulated package component 200 may then be mounted to a package substrate 301 using the conductive connectors 244 to form a package 300, in accordance with some embodiments. The package substrate 301 includes a substrate core 302 and bond pads 304 over the substrate core 302. The substrate core 302 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 302 may be an SOI substrate. Generally, an SOI substrate includes a layer of a semiconductor material such as epitaxial silicon, germanium, silicon germanium, SOI, SGOI, or combinations thereof. The substrate core 302 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 302.

The substrate core 302 may include active and passive devices (not shown). A wide variety of devices such as transistors, capacitors, resistors, combinations of these, and the like may be used to generate the structural and functional requirements of the design for the package 300. The devices may be formed using any suitable methods.

The substrate core 302 may also include metallization layers and vias (not shown), with the bond pads 304 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 302 is substantially free of active and passive devices.

In some embodiments, the conductive connectors 244 are reflowed to attach the package component 200 to the bond pads 304. The conductive connectors 244 electrically and/or physically couple the package substrate 301, including metallization layers in the substrate core 302, to the package component 200. In some embodiments, an underfill 308 may be formed between the package component 200 and the package substrate 301 and surrounding the conductive connectors 244. The underfill 308 may be formed by a capillary flow process after the package component 200 is attached or may be formed by a suitable deposition method before the package component 200 is attached. In some embodiments, passive devices (e.g., surface mount devices (SMDs), not shown) may also be attached to the package substrate 301 (e.g., to the bond pads 304). In some embodiments, a ring structure 310 may be attached to the package substrate 301 by an adhesive or the like. The ring structure 310 may provide structural support and improve rigidity of the package 300. In other embodiments, a lid, heat spreader, or the like may be attached to the package substrate 301 and/or the package component 200.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. Techniques described herein allow for the formation of larger redistribution interposers for packages or package components. Additionally, the techniques described herein allow for the formation of larger redistribution interposers having relatively fine conductive features. For example, the techniques described herein allow for a redistribution interposer to be formed having 2 μm linewidth conductive features in a region with dimensions of about 55 mm×68 mm or larger, or an area of about 3500 mm² or larger. Other dimensions are possible. The techniques described herein form pattern regions and stitched regions (e.g., overlap regions) of redistribution layers that allow for higher routability and conductive routing that can satisfy complex device integrated requirements. The pattern regions and stitched regions can overcome tool limitations by the use of multiple exposure processes. Additionally, the techniques described herein can form an interposer without the use of a local silicon interconnect (LSI) or the like. In this manner the techniques described herein can form a redistribution interposer having denser routing, reduced cost, larger size, and increased layout flexibility.

In some embodiments of the present disclosure, a method includes forming a first photoresist layer on a dielectric layer; performing a first light-exposure process on the first photoresist layer using a first photolithography mask, wherein during the first light-exposure process, a first region the first photoresist layer is blocked from being exposed, a second region of the first photoresist layer is exposed, and a third region of the first photoresist layer is exposed, wherein the second region encircles the first region and the third region encircles the second region; performing a second light-exposure process on the first photoresist layer using a second photolithography mask, wherein during the second light-exposure process, the first region of the first photoresist layer is exposed, the second region of the first photoresist layer is exposed, and the third region of the first photoresist layer is blocked from being exposed; and developing the first photoresist layer. In an embodiment, the pattern of the first photolithography mask has a larger linewidth than the pattern of the second photolithography mask. In an embodiment, the second region is contiguous with the first region and the third region. In an embodiment, the method includes performing an etch process to pattern a first dielectric layer using the developed first photoresist layer as an etch mask and depositing a conductive material on the patterned first dielectric layer. In an embodiment, the method includes performing a third light-exposure process on the first photoresist layer using the second photolithography mask, wherein during the third light-exposure process, the third region of the first photoresist layer is blocked from being exposed, a fourth region of the first photoresist layer is exposed, and a fifth region of the first photoresist layer is exposed, wherein the fifth region encircles the fourth region and the third region encircles the fifth region. In an embodiment, the second light-exposure process is performed before the first light-exposure process. In an embodiment, the second region has a width in the range of 1 μm to 50 μm. In an embodiment, developing the first photoresist layer exposes an underlying seed layer.

In some embodiments of the present disclosure, a method includes exposing a first pattern in a first pattern region of a first photoresist layer, wherein the first pattern has a first linewidth; exposing a second pattern in a second pattern region of the first photoresist layer, wherein the second pattern has a second linewidth that is smaller than the first linewidth, wherein the first pattern region laterally surrounds the second pattern region; performing a first developing process on the first pattern region and the second pattern region of the first photoresist layer to form a pattern in the first photoresist layer; and depositing a conductive material in the pattern of the first photoresist layer. In an embodiment, performing the first developing process exposes an underlying seed layer, wherein the conductive material is deposited on the exposed seed layer. In an embodiment, the first pattern overlaps the second pattern. In an embodiment, overlapping portions of the first pattern and the second pattern laterally surround the second pattern region. In an embodiment, the method includes removing the first photoresist layer and depositing a dielectric layer over the conductive material. In an embodiment, the method includes exposing the second pattern in a third pattern region of the first photoresist layer. In an embodiment, the third pattern region overlaps the second pattern region. In an embodiment, the first pattern region laterally surrounds the third pattern region.

In some embodiments of the present disclosure, a package includes a redistribution interposer that includes redistribution layers in dielectric layers, wherein each redistribution layer has a first region with a first pitch that surrounds a second region with a second pitch, wherein the second pitch is smaller than the first pitch, wherein the first region is adjacent each sidewall of the redistribution interposer; a semiconductor die bonded to a first side of the redistribution interposer; and a package substrate bonded to a second side of the redistribution interposer. In an embodiment, the first region of each redistribution layer has the same size. In an embodiment, the second region has an area of at least 3500 mm². In an embodiment, the redistribution interposer includes at least six redistribution layers

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing a first dielectric layer over a substrate;
exposing an inner region of the first dielectric layer to a first light pattern using a first light mask;
exposing an outer region of the first dielectric layer to a second light pattern using a second light mask, wherein the outer region of the first dielectric layer surrounds the inner region of the first dielectric layer; and
performing a first developing process on the first dielectric layer to form a plurality of first recesses in the inner region and the outer region of the first dielectric layer; and
depositing a conductive material in the plurality of first recesses.

2. The method of claim 1, wherein the first dielectric layer is a photosensitive material.

3. The method of claim 1, further comprising:
depositing a second dielectric layer over the first dielectric layer;
exposing an inner region of the second dielectric layer to a third light pattern using a third light mask;
exposing an outer region of the second dielectric layer to a fourth light pattern using a fourth light mask, wherein the outer region of the second dielectric layer surrounds the inner region of the second dielectric layer; and
performing a second developing process on the second dielectric layer to form a plurality of second recesses in the inner region and the outer region of the second dielectric layer.

4. The method of claim 3, wherein the second dielectric layer is deposited after the conductive material is deposited.

5. The method of claim 1, wherein a pitch of the first recesses in the inner region is smaller than a pitch of the first recesses in the outer region.

6. The method of claim 1, wherein the outer region extends partially into the inner region.

7. The method of claim 1, wherein a region of conductive material extends continuously from within the inner region of the first dielectric layer to within the outer region of the first dielectric layer.

8. The method of claim 1, wherein exposing the outer region of the first dielectric layer is performed before exposing the inner region of the first dielectric layer.

9. A method comprising:
performing a first exposure process on a first region of a photosensitive layer, wherein the first exposure process exposes the first region of the photosensitive layer to a first light pattern using a first photolithography mask, wherein the first region of the photosensitive layer surrounds a plurality of second regions of the photosensitive layer;
performing a plurality of second exposure processes on the plurality of second regions of the photosensitive layer, wherein respective second exposure processes expose respective second regions of the photosensitive layer to a second light pattern using a second photolithography mask;
developing the photosensitive layer to form a pattern in the first region of the photosensitive layer and the plurality of second regions of the photosensitive layer; and
depositing a conductive material in the pattern of the photosensitive layer.

10. The method of claim 9, wherein the first exposure process is further performed on a third region of the photosensitive layer, wherein at least one second exposure process of the plurality of second exposure processes is performed on the third region of the photosensitive layer.

11. The method of claim 9, wherein the second regions of the plurality of second regions of the photosensitive layer have a same size.

12. The method of claim 9, wherein a linewidth of the second light pattern is smaller than a linewidth of the first light pattern.

13. The method of claim 9, wherein at least two second regions of the plurality of second regions of the photosensitive layer partially overlap.

14. The method of claim 9, wherein adjacent second regions of the plurality of second regions are separated by the first region of the photosensitive layer.

15. The method of claim 9, wherein the plurality of second regions of the photosensitive layer remain unexposed to light during the first exposure process.

16. The method of claim 9, wherein the plurality of first regions of the photosensitive layer remain unexposed to light during the second exposure process.

17. A structure comprising:
a redistribution interposer comprising a plurality of redistribution layers in a plurality of dielectric layers, wherein a first redistribution layer of the plurality of redistribution layers comprises a plurality of first conductive lines and a plurality of second conductive lines, wherein the first conductive lines have a first linewidth that is smaller than a second linewidth of the plurality of second conductive lines, wherein the plurality of second conductive lines laterally surround the plurality of first conductive lines;
a first die connected to a second redistribution layer of the plurality of redistribution layers of the redistribution interposer; and
an encapsulant on the redistribution interposer and surrounding the first die.

18. The structure of claim 17, wherein the first redistribution layer comprises a plurality of third conductive lines that extend from respective first conductive lines to respective second conductive lines, wherein the third conductive lines have a third linewidth that is greater than the first linewidth and the second linewidth.

19. The structure of claim 18, wherein the plurality of third conductive lines have a bulging profile.

20. The structure of claim 17, wherein first conductive lines are offset from adjacent second conductive lines.
